(19) United States
(12) Patent Application Publication
(10) Pub. No.: US 2025/0221080 A1
(43) Pub. Date: Jul. 3, 2025

(54) IMAGE SENSOR

(71) Applicant: SAMSUNG ELECTRONICS CO., LTD., Suwon-si (KR)

(72) Inventors: Daehoon Kim, Suwon-si (KR); Junha Kang, Suwon-si (KR); Gwideok Ryan Lee, Suwon-si (KR)

(73) Assignee: SAMSUNG ELECTRONICS CO., LTD., Suwon-si (KR)

(21) Appl. No.: 18/915,984

(22) Filed: Oct. 15, 2024

(30) Foreign Application Priority Data
Jan. 3, 2024 (KR) 10-2024-0001067
Apr. 5, 2024 (KR) 10-2024-0046950

(51) Int. Cl. H01L 27/146; H01L 23/00; H01L 23/522

(52) U.S. Cl. CPC H10F 39/811; H01L 23/5225; H01L 24/08; H01L 24/80; H10F 39/018; H10F 39/809; H01L 2224/08145; H01L 2224/80895; H01L 2224/80896

(57) ABSTRACT

An image sensor is provided and includes a top layer including a first floating diffusion (FD) wiring structure connected to a FD node, and a first shield structure next to the first FD wiring structure. The image sensor further includes a middle layer bonded to and below the top layer, wherein the middle layer includes a source follower gate, a source follower source region, a second FD wiring structure connected to the first FD wiring structure and the source follower gate, a second shield structure connected to the first shield structure and the source follower source region, and a source follower landing pad between the second shield structure and the source follower source region and spaced apart from the source follower gate.

### CROSS-REFERENCE TO RELATED APPLICATION

This application is based on and claims priority under 35 U.S.C. § 119 to Korean Patent Application Nos. 10-2024-0001067, filed on Jan. 3, 2024, and 10-2024-0046950, filed on Apr. 5, 2024, in the Korean Intellectual Property Office, the disclosures of which are incorporated by reference herein in their entirety.

### BACKGROUND

### 1. Field

Embodiments of the present disclosure relate to an image sensor, and more particularly, to an image sensor capable of improving conversion gain.

### 2. Brief Description of Related Art

An image sensor for capturing images and converting them into electrical signals is used not only in consumer electronic devices like digital cameras, mobile phone cameras, and portable camcorders, but also in cameras mounted on an automobile, security devices, and robots. Pixels of image sensors are becoming smaller, and, as pixels become smaller, floating diffusion capacitance increases, which decreases conversion gain. Therefore, it is necessary to improve conversion gain.

### SUMMARY

According to embodiments of the present disclosure, an image sensor capable of improving conversion gain is provided.

According to embodiments of the present disclosure, an image sensor may be provided and include a top layer including: a first substrate; a floating diffusion (FD) node within the first substrate; a first FD wiring structure connected to the FD node; and a first shield structure next to the first FD wiring structure. The image sensor may further include a middle layer bonded to and below the top layer, wherein the middle layer includes: a second substrate; a source follower gate on the second substrate; a source follower source region in the second substrate; a second FD wiring structure connected to the first FD wiring structure and the source follower gate; a second shield structure connected to the first shield structure and the source follower source region; and a source follower landing pad between the second shield structure and the source follower source region and spaced apart from the source follower gate. The image sensor may further include a bottom layer bonded to and below the middle layer, wherein the bottom layer includes a third substrate and transistors on the third substrate.

According to embodiments of the present disclosure, an image sensor may be provided and include a top layer including: a first substrate; a floating diffusion (FD) node within the first substrate; a first FD wiring structure connected to the FD node; and a first shield structure next to the first FD wiring structure. The image sensor may further include a middle layer bonded to and below the top layer, wherein the middle layer includes: a second substrate including a second front surface and a second back surface opposite to the second front surface; a source follower gate on the second front surface of the second substrate; a source follower source region in the second substrate; a second FD wiring structure connected to the first FD wiring structure and the source follower gate; and a second shield structure connected to the first shield structure and the source follower source region. A bottom layer bonded to and below the middle layer, wherein the bottom layer includes a third substrate and transistors on the third substrate, wherein the second shield structure includes: a second shield bonding pad bonded to a first shield bonding pad included in the first shield structure; and an impurity region in the second substrate and connected to the second shield bonding pad.

According to embodiments of the present disclosure, an image sensor may be provided and include a top layer including: a first substrate; a pixel isolation layer in the first substrate and defining a pixel; a photo diode arranged in the first substrate and constituting the pixel; a transmission transistor for transmitting an electrical signal generated by the photo diode; a floating diffusion (FD) node in the first substrate and connected to the transmission transistor; a first FD wiring structure connected to the FD node; a first shield structure next to the first FD wiring structure; and a first wiring layer spaced apart from the first FD wiring structure and the first shield structure. The image sensor may further include a middle layer bonded to and below the top layer, wherein the middle layer includes: a second substrate; a source follower gate on the second substrate; a source follower source region in the second substrate; a second FD wiring structure connected to the first FD wiring structure and the source follower gate; a second shield structure connected to the first shield structure and the source follower source region; a source follower landing pad between the second shield structure and the source follower source region and surrounding the source follower gate; and a second wiring layer spaced apart from the second FD wiring structure and the second shield structure. The image sensor may further include a bottom layer bonded to and below the middle layer, wherein the bottom layer includes: a third substrate; transistors arranged on the third substrate; a third wiring layer connected to a transistor; and a third via plug between the transistor and the third wiring layer.

### BRIEF DESCRIPTION OF DRAWINGS

Embodiments of the present disclosure will be more clearly understood from the following detailed description taken in conjunction with the accompanying drawings in which:

FIG. 1 is a block diagram showing an image sensor according to an embodiment;

FIG. 2 is a circuit diagram of an image sensor according to an embodiment;

FIG. 3 is a schematic cross-sectional view for describing the structure of an image sensor according to an embodiment;

FIG. 4 is a plan view taken along a line X-X′ of FIG. 3;

FIG. 5 is a plan view taken along a line X-X′ of FIG. 3;

FIG. 6 is a schematic cross-sectional view for describing the structure of an image sensor according to an embodiment;

FIG. 7 is a schematic cross-sectional view for describing the structure of an image sensor according to an embodiment;

FIG. 8 is a schematic cross-sectional view for describing the structure of an image sensor according to an embodiment;

FIG. 9 is a plan view taken along a line Y-Y′ of FIG. 8;

FIG. 10 is a schematic cross-sectional view for describing the structure of an image sensor according to an embodiment;

FIG. 11 is a schematic cross-sectional view for describing the structure of an image sensor according to an embodiment;

FIG. 12 is a schematic cross-sectional view for describing the structure of an image sensor according to an embodiment;

FIG. 13 is a schematic cross-sectional view for describing the structure of an image sensor according to an embodiment;

FIG. 14 is a schematic cross-sectional view for describing the structure of an image sensor according to an embodiment;

FIGS. 15A and 15B are cross-sectional views for describing a method of manufacturing the image sensor of FIG. 3, according to an embodiment; and

FIGS. 16A to 16D are cross-sectional views for describing a method of manufacturing the image sensor of FIG. 8, according to an embodiment.

### DETAILED DESCRIPTION

In this disclosure, it should be understood that when any element is referred to as being “fastened,” “coupled,” or “connected” to another element, the element may be directly coupled or connected to another element, or there may be yet another element therebetween. On the other hand, in the description, when any element is referred to as being “directly fastened,” “directly coupled,” or “directly connected” to another element, it should be understood that there are no other elements therebetween.

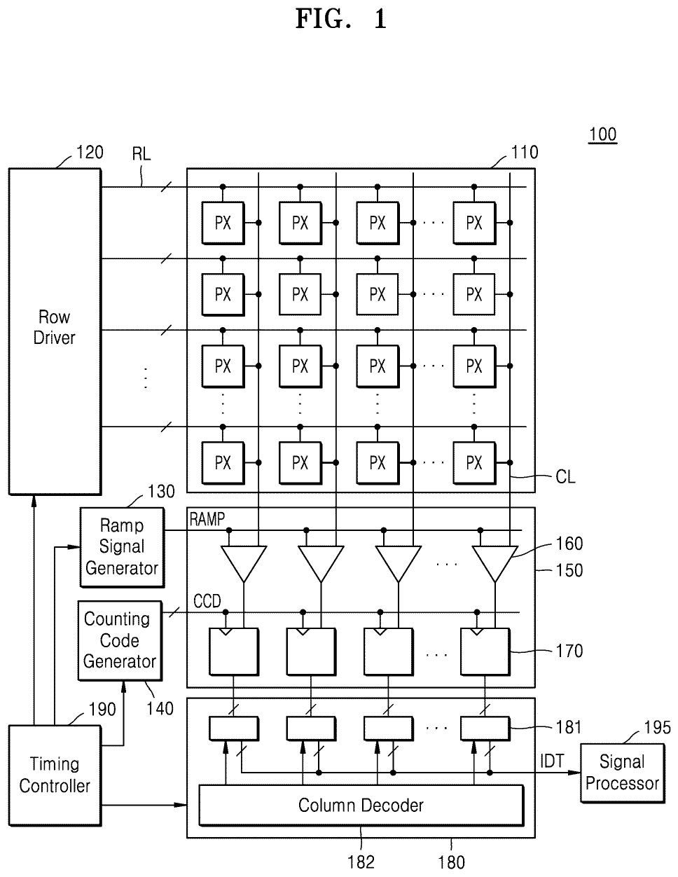

FIG. 1 is a block diagram showing an image sensor according to an embodiment.

In detail, the image sensor 100 may include a pixel array 110, a row driver 120, a ramp signal generator 130, a counting code generator 140, an analog-to-digital conversion (ADC) circuit 150, a data output circuit 180, and a timing controller 190. The image sensor 100 may further include a signal processor 195. A component including the ADC circuit 150 and the data output circuit 180 may be referred to as a read-out circuit.

The pixel array 110 may include a plurality of row lines RL and a plurality of column lines CL. The pixel array 110 may include a plurality of pixels PX connected to the plurality of row lines RL and the plurality of column lines CL and arranged in rows and columns. The plurality of pixels PX may be active pixel sensors (APS).

The plurality of pixels PX may each include at least one photoelectric conversion element, and a pixel PX may detect light by using the photoelectric conversion element and output an image signal, which is an electrical signal converted from detected light. For example, the photoelectric conversion element may include a photo diode, a photo transistor, a photo gate, or a pinned photo diode (PPD).

The plurality of pixels PX may each detect light in a particular spectral region. For example, some of the plurality of pixels PX may convert light in the red spectrum region into electrical signals, convert light in the green spectrum region into electrical signals, or convert light in the green spectrum region into electrical signals. However, embodiments of the present disclosure are not limited thereto, and at least some of the plurality of pixels may convert light in the white spectrum region into electrical signals.

In another example, at least some of the plurality of pixels PX may convert light in a different color spectrum region into electrical signals. For example, at least some of the plurality of pixels PX may convert light in any one from among the yellow spectrum region, the cyan spectrum region, and the magenta spectrum region into electrical signals.

A color filter may be disposed over each of the plurality of pixels PX to transmit light in a particular spectrum region therethrough. A color that may be detected by a corresponding one of the pixels PX may be determined according to the color filter. However, embodiments of the present disclosure are not limited thereto. According to some embodiments, a particular photoelectric conversion element may convert light in a particular wavelength band into an electrical signal according to the level of an electrical signal applied to the corresponding photoelectric conversion element.

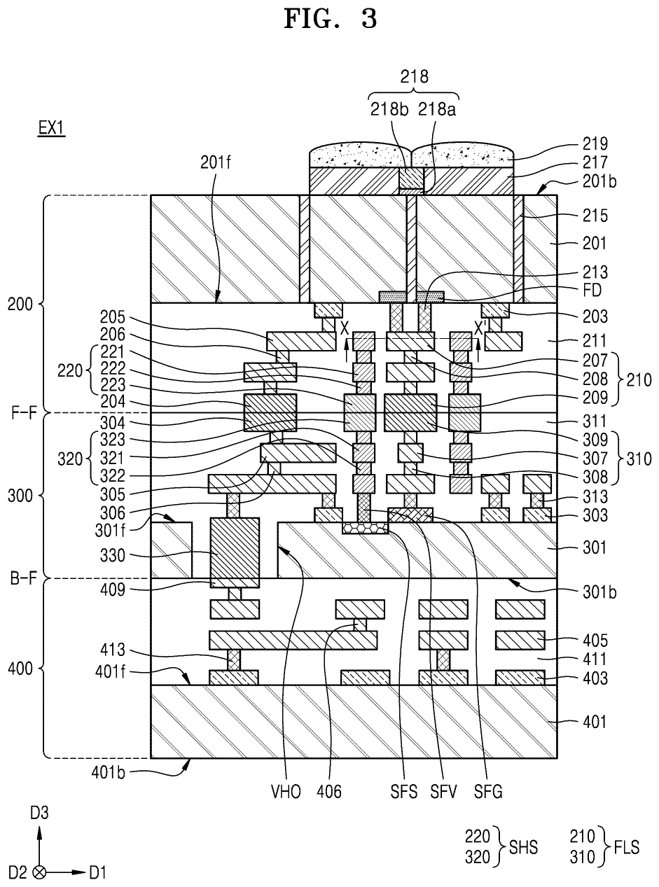

According to some embodiments, the plurality of pixels PX may each have a dual conversion gain. A dual conversion gain includes a low conversion gain and a high conversion gain. Here, a conversion gain refers to a rate at which charges accumulated in a floating diffusion node (or a floating diffusion region) is converted into a voltage. Charges generated by a photoelectric conversion element are transmitted to and accumulated in a floating diffusion node FD (see, e.g., FIG. 3), and charges accumulated in the floating diffusion node FD may be converted into a voltage according to the conversion gain. At this time, the conversion gain may vary according to the capacitance of the floating diffusion node FD. When the capacitance increases, the conversion gain may decrease. When the capacitance decreases, the conversion gain may increase.

The row driver 120 may drive the pixel array 110 row-by-row. The row driver 120 may decode a row control signal (e.g., an address signal) received from the timing controller 190. The row driver 120 may select at least one row line RL from among the plurality of row lines RL constituting the pixel array 110 in response to a decoded row control signal.

For example, the row driver 120 may generate a selection signal for selecting one from among a plurality of rows. The selection signal may be transmitted to the pixel array 110 through a row line RL. The pixel array 110 outputs a pixel signal (e.g., a pixel voltage) from a row selected by the selection signal provided from the row driver 120. The pixel signal may include a reset signal and an image signal. The row driver 120 may transmit control signals to the pixel array 110. The control signals may be signals for outputting pixel signals. The pixel PX may output a pixel signal by operating in response to control signals.

The ramp signal generator 130 may generate a ramp signal (e.g., ramp voltage) whose level rises or falls at a certain slope under the control of the timing controller 190. A ramp signal RAMP may be provided to each of a plurality of correlated double sampling (CDS) circuits 160 provided in the ADC circuit 150.

The counting code generator 140 may generate a counting code CCD under the control of the timing controller 190. The counting code CCD may be provided to each of a plurality of counter circuits 170. According to some embodiments, counting code generator 140 may be implemented as a gray code generator. The counting code generator 140 may generate a plurality of code values having a resolution according to a set number of bits as the counting code CCD. For example, when a 10-bit code is set, the counting code generator 140 may generate the counting code CCD including 1024 code values that sequentially increase or decrease.

The ADC circuit 150 may include a plurality of CDS circuits 160 and a plurality of counter circuits 170. The ADC circuit 150 may convert a pixel signal input from the pixel array 110 into a pixel value, which is a digital signal. Each pixel signal received through each of a plurality of column lines CL is converted into a pixel value, which is a digital signal, by a CDS circuit 160 and a counter circuit 170.

The CDS circuit 160 may compare a pixel signal received through the column line CL with the ramp signal RAMP and output a result of the comparison as a comparison result signal. When the level of the ramp signal RAMP is identical to the level of a pixel signal, the CDS circuit 160 may output a comparison signal that transitions from a first level (e.g., logic high) to a second level (e.g., logic low). A time point at which the level of the comparison signal transitions may be determined according to the level of the pixel signal.

The CDS circuit 160 may sample a pixel signal provided from the pixel PX according to a CDS method. The CDS circuit 160 may sample a reset signal received as a pixel signal, compare the reset signal with the ramp signal RAMP, and generate a comparison signal according to the reset signal. Afterwards, the CDS circuit 160 may sample an image signal correlated to the reset signal, compare the image signal with the ramp signal RAMP, and generate a comparison signal according to the image signal.

The counter circuit 170 may count time points at which the level of the comparison result signal output from the CDS circuit 160 transits and output a count value. According to some embodiments, counter circuit 170 may include a latch circuit and a computing circuit. The latch circuit receives the counting code CCD from the counting code generator 140 and the comparison signal from the CDS circuit 160, and may latch the code value of the counting code CCD at a time point at which the level of the comparison signal transitions.

The latch circuit may latch a code value corresponding to a reset signal. For example, the latch circuit may latch a code value corresponding to a reset signal and a code value corresponding to an image signal. For example, the latch circuit may latch the value of an image signal. The computing circuit may calculate the value of a reset signal and the value of an image signal, and generate the value of an image signal from which the reset level of the pixel PX is removed. The counter circuit 170 may output the value of an image signal from which the reset level is removed as a pixel value.

With respect to the present embodiment, it has been described that the image sensor 100 includes the counting code generator 140, and the counter circuit 170 includes a circuit that latches the code value of the counting code CCD received from the counting code generator 140. However, embodiments of the present disclosure are not limited thereto.

According to some embodiments, the image sensor 100 may not include a counting code generator 140 that is separate, and the counter circuit 170 may be implemented by an up-counter, in which a count value sequentially increases based on counting clock signals provided from the timing controller 190, and a computing circuit, an up/down counter, or a bit-wise inversion counter.

The data output circuit 180 may temporarily store and then output pixel values output from the ADC circuit 150. The data output circuit 180 may include a plurality of column memories 181 and a column decoder 182. A column memory 181 stores a pixel value received from the counter circuit 170. According to some embodiments, the plurality of column memories 181 may each be provided in the counter circuit 170. A plurality of pixel values stored in the plurality of column memories 181 may be output as image data IDT under the control of the column decoder 182.

The timing controller 190 may output control signals to the row driver 120, the ramp signal generator 130, the counting code generator 140, the ADC circuit 150, and the data output circuit 180, thereby controlling operations or timings of the row driver 120, the ramp signal generator 130, the counting code generator 140, the ADC circuit 150, and the data output circuit 180.

The signal processor 195 may perform noise reducing processing, gain adjustment, waveform formulation, interpolation processing, white balance processing, gamma processing, edge emphasis processing, vining, etc., with respect to image data. In some embodiments, the signal processor 195 may be provided in a processor outside the image sensor 100.

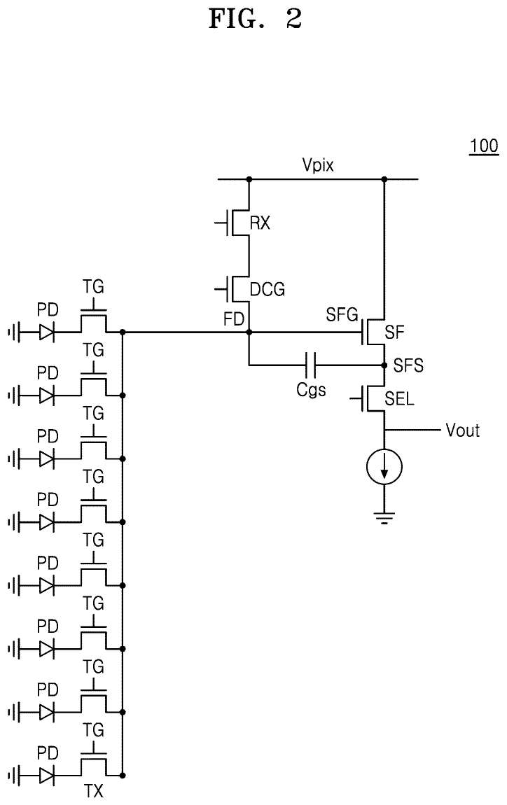

FIG. 2 is a circuit diagram of an image sensor according to an embodiment.

Referring to FIG. 2, the image sensor 100 may include a plurality of photo diodes PD, a plurality of transmission transistors TX, a floating diffusion node FD, a conversion gain transistor DCG, a reset transistor RX, a source follower transistor SF, and a select transistor SEL.

A transmission transistor TX, the conversion gain transistor DCG, the reset transistor RX, the source follower transistor SF, and the select transistor SEL include a transmission gate TG, a conversion gain gate, a reset gate, a source follower gate SFG, and a select gate, respectively.

According to some embodiments, the transmission gate TG may be a vertical gate. According to some embodiments, the conversion gain gate, the reset gate, the source follower gate SFG, and the select gate may each be a planar gate.

A photo diode PD may generate charges in proportion to an amount of incident light. The photo diode PD may generate electrons (i.e., negative charges) and holes (i.e., positive charges) in response to incident light.

According to some embodiments, eight photo diodes PD may be provided. The eight photo diodes PD may share one floating diffusion node FD, the reset transistor RX, the conversion gain transistor DCG, the source follower transistor SF, and the select transistor SEL. However, providing eight photo diodes PD is merely an example embodiment, and the number of the photo diodes PD is not limited thereto.

The transmission gate TG is disposed between the photo diode PD and the floating diffusion node FD, and may transmit charges generated by the photo diode PD to the floating diffusion node FD. The transmission transistor TX may include the transmission gate TG, a drain region connected to the photo diode PD, and a source region connected to the floating diffusion node FD.

The conversion gain transistor DCG may include a conversion gain gate, a source region connected to a drain region of the reset transistor RX, and a source region connected to the floating diffusion node FD.

The conversion gain transistor DCG may change the capacitance of the floating diffusion node FD according to a conversion gain signal. When the conversion gain transistor DCG is turned on, the capacitance of the floating diffusion node FD increases, and thus the image sensor 100 may operate in a low conversion gain mode. On the contrary, when the conversion gain transistor DCG is turned off, the capacitance of the floating diffusion node FD decreases, and thus the image sensor 100 may operate in a high conversion gain mode.

The reset transistor RX may include a reset gate, a source region connected to a power voltage Vpix, and a drain region connected to the source region of the conversion gain transistor DCG. When the reset transistor RX is turned on according to a reset control signal and the conversion gain transistor DCG is turned on according to a conversion gain signal, the floating diffusion node FD may be reset based on the power voltage Vpix. In detail, charges accumulated in the floating diffusion node FD may be discharged and the floating diffusion node FD may be reset. At this time, a reset signal corresponding to the voltage level of the floating diffusion node FD may be output.

The source follower transistor SF may include the source follower gate SFG connected to the floating diffusion node FD, a source follower source region SFS connected to a source region of the select transistor SEL, and a drain region connected to the power voltage Vpix.

The potential of the floating diffusion node FD changes according to the amount of charges accumulated in the floating diffusion node FD, and the source follower transistor SF may amplify a potential change in the floating diffusion node FD and output an amplified potential change to the source follower source region SFS.

A gate-source capacitance Cgs may be formed between the source follower transistor SF and the floating diffusion node FD. The gate-source capacitance Cgs is distinct from a parasitic capacitance applied to the floating diffusion node FD. The gate-source capacitance Cgs may reduce the value of the parasitic capacitance applied to the floating diffusion node FD. As a result, the conversion gain may increase due to the gate-source capacitance Cgs.

The select transistor SEL may include a select gate, a source region connected to the source of the source follower transistor SF, and a drain region connected to a line of an output voltage Vout.

FIG. 3 is a schematic cross-sectional view for describing the structure of an image sensor according to an embodiment.

In detail, an image sensor EX1 may be an embodiment of the image sensor 100 of FIG. 1. The image sensor EX1 may include the pixels PX of FIG. 1. The image sensor EX1 may include a top layer 200, a middle layer 300, and a bottom layer 400.

In the image sensor EX1, the middle layer 300 and the top layer 200 may be stacked on the bottom layer 400. The image sensor EX1 may include three layers in which the middle layer 300 and the top layer 200 are stacked on the bottom layer 400. The image sensor EX1 may include three layers in which the bottom layer 400, the middle layer 300, and the top layer 200 are bonded to one another. The image sensor EX1 may include a floating diffusion (FD) wiring structure FLS and a shield structure SHS.

A transistor described below may include a planar transistor, a multi-bridge channel (MBC) transistor, a gate-all-around (GAA) transistor, or a field-effect transistor (Fin FET).

The top layer 200 may include a first substrate 201, a plurality of first transistors 203, a first wiring layer 205, a first contact plug 206, a first frontside bonding pad 204, a first via plug 213, a first insulation layer 211, a pixel isolation layer 215, a color filter 217, a lens 219, a first floating diffusion (FD) wiring structure 210, and a first shield structure 220.

The first substrate 201 may be a semiconductor substrate or a silicon-on-insulator (SOI) substrate. The semiconductor substrate may include, for example, a silicon substrate, a germanium substrate, or a silicon-germanium substrate. The first substrate 201 may include a first front surface 201f and a first back surface 201b opposite to the first front surface 201f. Photo diodes PD (see FIG. 2) may be arranged on the first substrate 201.

According to some embodiments, one photo diode PD (see FIG. 2) may be disposed in correspondence to one color filter 217 and one lens 219. According to some embodiments, a plurality of photo diodes PD (see FIG. 2) may be arranged in correspondence to one color filter 217 and one lens 219.

The color filter 217 and the lens 219 may be arranged on the first back surface 201b of the first substrate 201. The color filter 217 and the lens 219 may be sequentially stacked on the first back surface 201b of the first substrate 201.

The pixel isolation layer 215 may be disposed within the first substrate 201. The pixel isolation layer 215 may function to isolate the plurality of pixels PX in FIG. 1 from one another. The pixel isolation layer 215 may include two or more materials. The pixel isolation layer 215 may include, for example, a semiconductor material and an insulation material having a refractive index different from a refractive index of the first substrate 201. The semiconductor material may include, for example, a polysilicon film or a silicon germanium film doped with an impurity. The impurity doped into a polysilicon film or a silicon germanium film may be, for example, one from among boron, phosphorus, and arsenic. The insulation material may include, for example, silicon oxide. The pixel isolation layer 215 may include a metal film instead of a semiconductor material.

The first transistors 203 may be arranged on the first front surface 201f. For example, the first transistors 203 may include, but is not limited to, a transmission transistor TX (see FIG. 2). When a first transistor 203 corresponds to a transmission transistor TX (see FIG. 2), some of first source and drain regions constituting the first transistor 203 may be floating diffusion nodes FD. Illustration of other ones of the first source and drain regions are omitted for convenience.

In this specification, a first horizontal direction D1 is defined as a direction parallel to the first front surface 201f of the first substrate 201, a second horizontal direction D2 is defined as a direction parallel to the first front surface 201f of the first substrate 201 and intersecting the first horizontal direction D1, and a vertical direction D3 is defined as a direction perpendicular to the first front surface 201f of the first substrate 201.

The first contact plug 206 and the first wiring layer 205 may be connected to the first transistor 203. The first contact plug 206 and the first wiring layer 205 may be arranged on the first front surface 201f of the first substrate 201. A plurality of first wiring layers 205 may be provided. From among the plurality of first wiring layers 205, two different ones of the first wiring layers 205 may be located at different vertical levels. In other words, the plurality of first wiring layers 205 may form a multilayer structure.

In this specification, the term “vertical level” is defined as the height in the vertical direction D3 from an arbitrary point to a particular point. For example, the vertical level of the first wiring layer 205 may correspond to the height in the vertical direction D3 from a third back surface 401b of a third substrate 401 to the first wiring layer 205.

In this specification, the expression “connected” corresponds to a concept that includes not only a direct contact between one component and another component, but also an indirect connection through another component. Also, the expression “connected” corresponds to a concept that includes an electrical connection between one component and another component.

The first contact plug 206 may connect at least two first wiring layers 205 at different vertical levels to each other. The first contact plug 206 may connect the first wiring layer 205 and the first frontside bonding pad 204 to each other. The first frontside bonding pad 204 may be disposed at a bottom of the top layer 200. The first frontside bonding pad 204 may be connected to a second frontside bonding pad 304. The first wiring layer 205 and the first contact plug 206 may be connected to the second frontside bonding pad 304 through the first frontside bonding pad 204. The first wiring layer 205, the first contact plug 206, and the first frontside bonding pad 204 may include a metal (e.g., copper (Cu) or tungsten (W)).

The floating diffusion node FD may be disposed within the first substrate 201. The floating diffusion node FD may correspond to the floating diffusion node FD of FIG. 2. The floating diffusion node FD may be a region doped with an impurity in the first substrate 201. The impurity may have P-type conductivity or N-type conductivity.

The first via plug 213 may be connected to the floating diffusion node FD. The first via plug 213 may be disposed on the first front surface 201f of the first substrate 201. The first via plug 213 may include a metal (e.g., Cu or W).

The first FD wiring structure 210 may be connected to the first via plug 213. The first FD wiring structure 210 may be disposed on the first front surface 201f of the first substrate 201. The first FD wiring structure 210 may be connected to the floating diffusion node FD through the first via plug 213. The first FD wiring structure 210 may be connected to the floating diffusion node FD.

The first FD wiring structure 210 may include a first FD wiring layer 207, a first FD plug 208, and a first FD bonding pad 209. A plurality of first FD wiring layers 207 may be provided. From among the plurality of first FD wiring layers 207, two different ones of the first FD wiring layers 207 may be located at different vertical levels. In other words, the plurality of first FD wiring layers 207 may form a multilayer structure. At least one of the plurality of first FD wiring layers 207 and at least one of the plurality of first wiring layers 205 may be located at the same vertical level.

The first FD plug 208 may connect at least two first FD wiring layers 207 at different vertical levels to each other. The first FD plug 208 may connect the first FD wiring layer 207 and the first FD bonding pad 209 to each other. The first FD bonding pad 209 may be disposed at a bottom of the top layer 200. The first FD wiring layer 207 and the first FD plug 208 may be connected to a second FD bonding pad 309 through the first FD bonding pad 209. The first FD wiring layer 207, the first FD plug 208, and the first FD bonding pad 209 may include a metal (e.g., Cu or W).

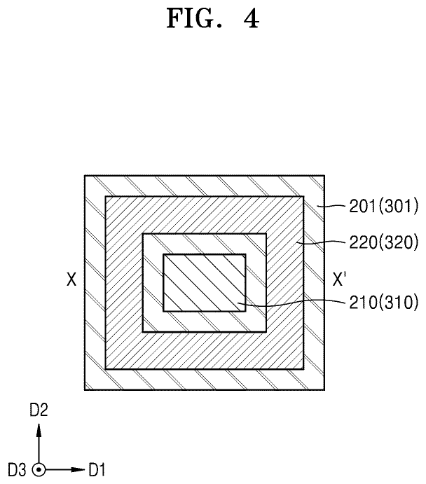

FIG. 4 is a plan view taken along a line X-X′ of FIG. 3.

Referring to FIGS. 3 and 4, the first shield structure 220 may be disposed on the first front surface 201f of the first substrate 201. The first shield structure 220 may include a first shield wiring layer 221, a first shield plug 222, and a first shield bonding pad 223.

A plurality of first shield wiring layers 221 may be provided. From among the plurality of first shield wiring layers 221, two different ones of the first shield wiring layers 221 may be located at different vertical levels. In other words, the plurality of first shield wiring layers 221 may form a multilayer structure. At least one of the plurality of first shield wiring layers 221 and at least one of the plurality of first wiring layers 205 may be located at the same vertical level.

The first shield plug 222 may connect at least two first shield wiring layers 221 at different vertical levels to each other. The first shield plug 222 may connect the first shield wiring layer 221 and the first shield bonding pad 223 to each other. The first shield bonding pad 223 may be disposed at a bottom of the top layer 200. The first shield wiring layer 221 and the first shield plug 222 may be connected to a second shield bonding pad 323 through the first shield bonding pad 223. The first shield wiring layer 221, the first shield plug 222, and the first shield bonding pad 223 may include a metal (e.g., Cu or W).

The first shield structure 220 may be spaced apart from the first FD wiring structure 210 in the first horizontal direction D1 and the second horizontal direction D2. The first shield structure 220 may be spaced apart from the first wiring layer 205 and the first contact plug 206 in the first horizontal direction D1 and the second horizontal direction D2. The first shield structure 220 may surround the floating diffusion node FD and the first FD wiring structure 210. In detail, the first shield wiring layer 221 may surround the first FD wiring layer 207 at the same vertical level as the first shield wiring layer 221. The plurality of first shield wiring layers 221 may be respectively arranged at all vertical levels at which the plurality of first FD wiring layers 207 are respectively arranged. Therefore, every one of the plurality of first FD wiring layers 207 may be surrounded by at least one first shield wiring layer 221.

Referring back to FIG. 3, the first insulation layer 211 may be disposed on the first front surface 201f of the first substrate 201. The first wiring layer 205, a first contact plug 206, the first FD wiring structure 210, the first shield structure 220, and the first via plug 213 may be arranged in the first insulation layer 211. However, the first insulation layer 211 may not cover the bottom surface of the first frontside bonding pad 204, the bottom surface of the first FD bonding pad 209, and the bottom surface of the first shield bonding pad 223. The first insulation layer 211 may have a single-layer structure or a multilayer structure. The first insulation layer 211 may include an insulation material such as silicon oxide, silicon nitride, silicon oxynitride, or a combination thereof.

The middle layer 300 may include a second substrate 301, a plurality of second transistors 303, the source follower gate SFG, the source follower source region SFS, a source follower via SFV, a backside bonding through via 330, a second wiring layer 305, a second contact plug 306, the second frontside bonding pad 304, a second via plug 313, a second floating diffusion (FD) wiring structure 310, a second shield structure 320, and a second insulation layer 311.

The first frontside bonding pad 204 included in the top layer 200 may be bonded to the second frontside bonding pad 304 included in the middle layer 300. The first FD bonding pad 209 included in the top layer 200 may be bonded to the second FD bonding pad 309 included in the middle layer 300. The first shield bonding pad 223 included in the top layer 200 may be bonded to the second shield bonding pad 323 included in the middle layer 300. The first insulation layer 211 included in the top layer 200 may be bonded to the second insulation layer 311 included in the middle layer 300. The top layer 200 and the middle layer 300 may have a boundary surface F-F at which the front surface of the top layer 200 and the front surface of the middle layer 300 are bonded to each other.

The second substrate 301 may be a semiconductor substrate or a silicon-on-insulator (SOI) substrate. The semiconductor substrate may include, for example, a silicon substrate, a germanium substrate, or a silicon-germanium substrate. The second substrate 301 may include a second front surface 301f and a second back surface 301b opposite to the second front surface 301f. The second transistors 303 may be formed on the second front surface 301f.

The second transistors 303 may be arranged on the second front surface 301f. The second transistors 303 may include any one of the transistors described in FIG. 2, excluding the source follower transistor SF (see FIG. 2). For example, the second transistors 303 may include any one from among the conversion gain transistor DCG (see FIG. 2), the reset transistor RX (see FIG. 2), and the select transistor SEL (see FIG. 2). In FIG. 3, second source and drain regions constituting the second transistors 303 are arranged in the second substrate 301, but illustration thereof is omitted for convenience.

The source follower gate SFG constituting the source follower transistor SF (see FIG. 2) may be disposed on the second front surface 301f. The source follower source region SFS constituting the source follower transistor SF (see FIG. 2) may be disposed in the second substrate 301. The source follower source region SFS may be a region doped with an impurity in the second substrate 301. The impurity may have P-type conductivity or N-type conductivity.

A backside bonding through via 330 may be disposed in a through via hole VHO penetrating through the second substrate 301. The backside bonding through via 330 may be spaced apart from the second substrate 301 with the second insulation layer 311 therebetween.

The second contact plug 306 and the second wiring layer 305 may be connected to the second transistor 303 through the second via plug 313. The second contact plug 306, the second wiring layer 305, and the second via plug 313 may be arranged on the second front surface 301f of the second substrate 301. A plurality of second wiring layers 305 may be provided. From among the plurality of second wiring layers 305, two different ones of the second wiring layers 305 may be located at different vertical levels. In other words, the plurality of second wiring layers 305 may form a multilayer structure.

The second contact plug 306 may connect at least two second wiring layers 305 at different vertical levels to each other. The second contact plug 306 may connect the second wiring layer 305 and the second frontside bonding pad 304 to each other. The second frontside bonding pad 304 may be disposed at a top of the middle layer 300. The second frontside bonding pad 304 may be connected to the first frontside bonding pad 204. The second wiring layer 305 and the second contact plug 306 may be connected to the first frontside bonding pad 204 through the second frontside bonding pad 304. The second wiring layer 305, the second contact plug 306, the second via plug 313, and the second frontside bonding pad 304 may include a metal (e.g., Cu or W).

The second FD wiring structure 310 may be connected to the second via plug 313. The second FD wiring structure 310 may be disposed on the second front surface 301f of the second substrate 301. The second FD wiring structure 310 may be connected to the source follower gate SFG through the second via plug 313. The second FD wiring structure 310 may be connected to the source follower gate SFG.

The second FD wiring structure 310 may include a second FD wiring layer 307, a second FD plug 308, and the second FD bonding pad 309. A plurality of second FD wiring layers 307 may be provided. From among the plurality of second FD wiring layers 307, two different ones of the second FD wiring layers 307 may be located at different vertical levels. In other words, the plurality of second FD wiring layers 307 may form a multilayer structure. At least one of the plurality of second FD wiring layers 307 and at least one of the plurality of second wiring layers 305 may be located at the same vertical level.

The second FD plug 308 may connect at least two second FD wiring layers 307 at different vertical levels to each other. The second FD plug 308 may connect the second FD wiring layer 307 and the second FD bonding pad 309 to each other. The second FD bonding pad 309 may be disposed at a top of the middle layer 300. The second FD bonding pad 309 may connect the second FD wiring layer 307 and the second FD plug 308 to the first FD bonding pad 209. The second FD wiring layer 307, the second FD plug 308, and the second FD bonding pad 309 may include a metal (e.g., Cu or W).

Referring to FIGS. 3 and 4, the second shield structure 320 may be disposed on the second front surface 301f of the second substrate 301. The second shield structure 320 may include a second shield wiring layer 321, a second shield plug 322, and the second shield bonding pad 323.

A plurality of second shield wiring layers 321 may be provided. From among the plurality of second shield wiring layers 321, two different ones of the second shield wiring layers 321 may be located at different vertical levels. In other words, the plurality of second shield wiring layers 321 may form a multilayer structure. At least one of the plurality of second shield wiring layers 321 and at least one of the plurality of second wiring layers 305 may be located at the same vertical level.

The second shield plug 322 may connect at least two second shield wiring layers 321 at different vertical levels to each other. The second shield plug 322 may connect the second shield wiring layer 321 and the second shield bonding pad 323 to each other. The second shield bonding pad 323 may be disposed at a top of the middle layer 300. The second shield wiring layer 321 and the second shield plug 322 may be connected to the first shield bonding pad 223 through the second shield bonding pad 323. The second shield wiring layer 321, the second shield plug 322, and the second shield bonding pad 323 may include a metal (e.g., Cu or W).

The second shield structure 320 may be spaced apart from the second FD wiring structure 310 in the first horizontal direction D1 and the second horizontal direction D2. The second shield structure 320 may be spaced apart from the second wiring layer 305 and the second contact plug 306 in the first horizontal direction D1 and the second horizontal direction D2. The second shield structure 320 may surround the second FD wiring structure 310. In detail, the second shield wiring layer 321 may surround the second FD wiring layer 307 at the same vertical level as the second shield wiring layer 321. The plurality of second shield wiring layers 321 may be respectively arranged at all vertical levels at which the plurality of second FD wiring layers 307 are respectively arranged. Therefore, every one of the plurality of second FD wiring layers 307 may be surrounded by at least one second shield wiring layer 321.

The second shield structure 320 may be connected to the source follower source region SFS through the source follower via SFV. The second shield structure 320 may be connected to the source follower source region SFS.

Referring back to FIG. 3, the second insulation layer 311 may be disposed on the second front surface 301f of the second substrate 301. The second insulation layer 311 may also be provided between the backside bonding through via 330 and the second substrate 301. The second wiring layer 305, the second contact plug 306, the second FD wiring structure 310, the second shield structure 320, and the second via plug 313 are arranged in the second insulation layer 311. However, the second insulation layer 311 may not cover the top surface of the second frontside bonding pad 304, the top surface of the second FD bonding pad 309, and the top surface of the second shield bonding pad 323. The second insulation layer 311 may have a single-layer structure or a multilayer structure. The second insulation layer 311 may include an insulation material such as silicon oxide, silicon nitride, silicon oxynitride, or a combination thereof.

Referring to FIGS. 3 and 4, the first FD wiring structure 210 and the second FD wiring structure 310 may together constitute the FD wiring structure FLS. The first shield structure 220 and the second shield structure 320 may together constitute the shield structure SHS.

The FD wiring structure FLS may be connected to the floating diffusion node FD and the source follower gate SFG. The shield structure SHS may be connected to the source follower source region SFS. The shield structure SHS may surround the floating diffusion node FD and the FD wiring structure FLS. In a plan view, the floating diffusion node FD and the FD wiring structure FLS may be arranged within the shield structure SHS.

Referring back to FIG. 3, the bottom layer 400 may include the third substrate 401, a plurality of third transistors 403, a third wiring layer 405, a third contact plug 406, a third frontside bonding pad 409, a third via plug 413, and a third insulation layer 411.

The backside bonding through via 330 included in the middle layer 300 may be bonded to the third frontside bonding pad 409 included in the bottom layer 400. The second substrate 301 and the second insulation layer 311 included in the middle layer 300 may be bonded to the third insulation layer 411 included in the bottom layer 400. The middle layer 300 and the bottom layer 400 may have a boundary surface B-F at which the back surface of the middle layer 300 and the front surface of the bottom layer 400 are bonded to each other.

The third substrate 401 may be a semiconductor substrate or a silicon-on-insulator (SOI) substrate. The semiconductor substrate may include, for example, a silicon substrate, a germanium substrate, or a silicon-germanium substrate. The third substrate 401 may include a third front surface 401f and a third back surface 401b opposite to the third front surface 401f. The third transistors 403 may be arranged on the third front surface 401f. In FIG. 3, fourth source and drain regions constituting the third transistors 403 are arranged in the third substrate 401, but illustration thereof is omitted for convenience.

The third contact plug 406 and the third wiring layer 405 may be connected to the third transistor 403 through the third via plug 413. The third wiring layer 405 may be connected to the third frontside bonding pad 409 through the third contact plug 406. The third contact plug 406 and the third wiring layer 405 may be connected to the third frontside bonding pad 409. The third frontside bonding pad 409, the third wiring layer 405, the third contact plug 406, and the third via plug 413 may include a metal (e.g., Cu or W).

The third insulation layer 411 may be disposed on the third front surface 401f of the third substrate 401. The third wiring layer 405, the third contact plug 406, and the third via plug 413 may be disposed in the third insulation layer 411. However, the third insulation layer 411 may not cover the top surface of the third frontside bonding pad 409. The third insulation layer 411 may have a single-layer structure or a multilayer structure. The third insulation layer 411 may include an insulation material such as silicon oxide, silicon nitride, silicon oxynitride, or a combination thereof.

The image sensor EX1 according to embodiments of the present disclosure may include the floating diffusion node FD, the FD wiring structure FLS connected to the floating diffusion node FD and the source follower gate SFG, and the shield structure SHS connected to the source follower source region SFS. The shield structure SHS may be spaced apart from the floating diffusion node FD and the FD wiring structure FLS in the first horizontal direction D1 and the second horizontal direction D2. The shield structure SHS may surround the floating diffusion node FD and the FD wiring structure FLS. Therefore, capacitance may be formed between the FD wiring structure FLS and the shield structure SHS. The capacitance may correspond to the gate-source capacitance Cgs described above with reference to FIG. 2. As the gate-source capacitance Cgs of FIG. 2 is formed between the FD wiring structure FLS and the shield structure SHS, the conversion gain may be improved.

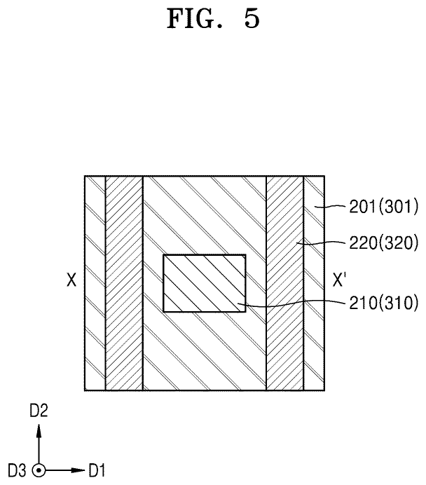

FIG. 5 is a plan view taken along a line X-X′ of FIG. 3. Hereinafter, the arrangement of the shield structure SHS will be described with reference to FIGS. 3 and 5. Hereinafter, only descriptions different from the descriptions given above with reference to FIGS. 3 and 4 will be given, and descriptions identical to those given above may be omitted.

Referring to FIGS. 3 and 5, the shield structure SHS may not surround the floating diffusion node FD and the FD wiring structure FLS. First shield structures 220 included in the shield structure SHS may be arranged on both sides of the FD wiring structure FLS and extend in the second horizontal direction D2. Alternatively, the first shield structures 220 included in the shield structure SHS may be arranged on both sides of the FD wiring structure FLS and extend in the first horizontal direction D1.

Second shield structures 320 included in the shield structure SHS may be arranged on both sides of the FD wiring structure FLS and extend in the second horizontal direction D2. Alternatively, the second shield structures 320 included in the shield structure SHS may be arranged on both sides of the FD wiring structure FLS and extend in the first horizontal direction D1. The first shield structure 220 and the second shield structure 320 may or may not overlap each other in the vertical direction D3. However, the first shield structure 220 and the second shield structure 320 may be connected to each other.

Alternatively, the first shield structure 220 and the second shield structure 320 may each be disposed on only one side of the FD wiring structure FLS and extend in the first horizontal direction D1 or the second horizontal direction D2. Even in this case, capacitance may be formed between the shield structure SHS including the first shield structure 220 and the second shield structure 320 and the FD wiring structure FLS.

According to embodiments, the first shield structures 220 arranged on both sides of the FD wiring structure FLS may be connected to each other. According to embodiments, the second shield structures 320 arranged on both sides of the FD wiring structure FLS may be connected to each other.

In the image sensor EX1 according to embodiments of the present disclosure, the shield structure SHS may not surround the FD wiring structure FLS. The first shield structure 220 and the second shield structure 320 of the shield structure SHS may each be disposed on both sides or only one side of the FD wiring structure FLS. Therefore, the area occupied by the shield structure SHS within the image sensor EX1 may be reduced. Also, even in this case, capacitance may be formed between the shield structure SHS and the FD wiring structure FLS, and the conversion gain may be improved. For the above-stated reasons, the degree of integration and the conversion gain of the image sensor EX1 may be improved.

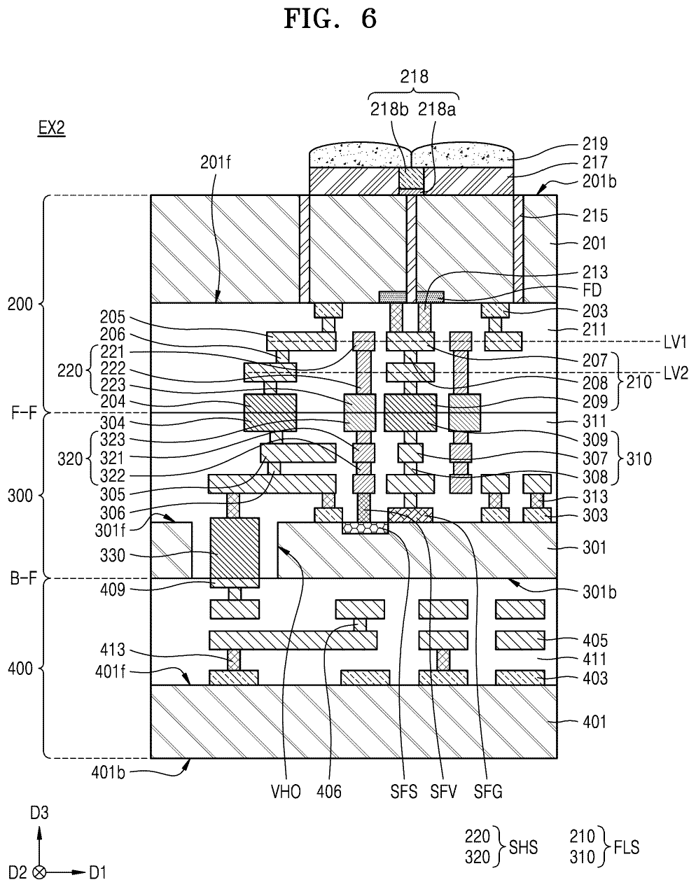

FIG. 6 is a schematic cross-sectional view for describing the structure of an image sensor according to an embodiment.

In detail, an image sensor EX2 may be an embodiment of the image sensor 100 of FIG. 1. The image sensor EX2 may include the pixels PX of FIG. 1. The image sensor EX2 may be substantially identical to the image sensor EX1 of FIG. 3, except that the top layer 200 is different from that of the image sensor EX1. In FIG. 6, descriptions identical to those given above with reference to FIGS. 3 and 4 may be briefly given or omitted.

The image sensor EX2 may include the top layer 200, the middle layer 300, and the bottom layer 400. The image sensor EX2 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The first FD wiring structure 210 may include the first FD wiring layer 207, the first FD plug 208, and the first FD bonding pad 209. A plurality of first FD wiring layers 207 may be provided. From among the plurality of first FD wiring layers 207, two different ones of the first FD wiring layers 207 may be located at different vertical levels. In other words, the plurality of first FD wiring layers 207 may form a multilayer structure.

For example, any one of the plurality of first FD wiring layers 207 may be disposed at a first vertical level LV1, and another one of the plurality of first FD wiring layers 207 may be disposed at a second vertical level LV2. The first vertical level LV1 and the second vertical level LV2 may be located between the first front surface 201f of the first substrate 201 and the bottom surface of the top layer 200. The second vertical level LV2 may be different from the first vertical level LV1. For example, the second vertical level LV2 may be lower than the first vertical level LV1.

Any one of the plurality of first wiring layers 205 may be disposed at the first vertical level LV1, and another one of the plurality of first wiring layers 205 may be disposed at the second vertical level LV2. According to embodiments, in addition to the first vertical level LV1 and the second vertical level LV2, there may be other vertical levels at which the first FD wiring layers 207 and the first wiring layers 205 are arranged. This may vary according to the embodiment of the image sensor EX2 to be manufactured.

The first shield structure 220 may include the first shield wiring layer 221, the first shield plug 222, and the first shield bonding pad 223. The first shield wiring layer 221 may be disposed at some of the vertical levels where the first FD wiring layers 207 are arranged and may not be disposed at some others of the vertical levels. For example, as shown in FIG. 6, the first shield wiring layer 221 may be disposed at the first vertical level LV1 and may not be disposed at the second vertical level LV2. The first shield bonding pad 223 and the first shield wiring layer 221 disposed at the first vertical level LV1 may be connected to each other through the first shield plug 222. The first shield wiring layer 221 disposed at the first vertical level LV1 may surround the first FD wiring structure 210.

The description of the first shield wiring layer 221 may also be applied similarly with respect to the second shield wiring layer 321 constituting the middle layer 300. In other words, the second shield wiring layers 321 may be disposed at some of the vertical levels where the second FD wiring layers 307 are arranged and may not be disposed at some others of the vertical levels. This may vary according to the embodiment of the image sensor EX2 to be manufactured. However, for convenience of explanation, repeated descriptions of the second shield wiring layer 321 and the second FD wiring layer 307 may be omitted.

The first shield wiring layers 221 of the image sensor EX2 according to embodiments of the present disclosure may be disposed at some of the vertical levels at which the first FD wiring layers 207 are arranged and may not be arranged in some others of the vertical levels. For example, the first shield wiring layer 221 may be disposed at the first vertical level LV1 and may not be disposed at the second vertical level LV2. In other words, the first shield wiring layer 221 may be omitted at a particular vertical level. Therefore, it may be determined whether to omit the first shield wiring layer 221 according to the degree of integration of various wires arranged at each vertical level. Even in this case, capacitance may be formed between the shield structure SHS and the FD wiring structure FLS. Therefore, the conversion gain of the image sensor EX2 may be improved and, at the same time, the degree of wiring freedom may be increased.

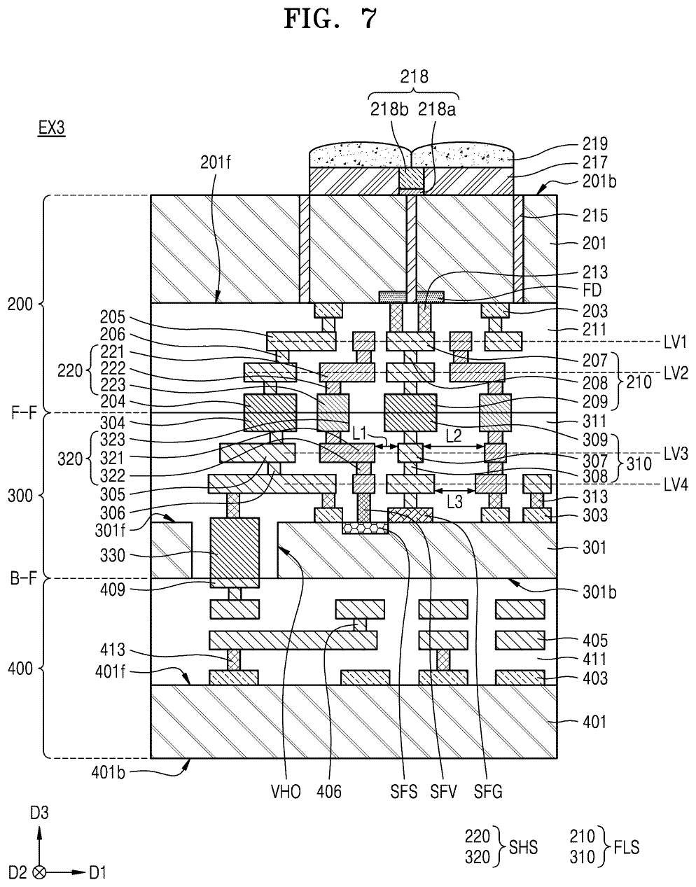

FIG. 7 is a schematic cross-sectional view for describing the structure of an image sensor according to an embodiment.

In detail, an image sensor EX3 may be an embodiment of the image sensor 100 of FIG. 1. The image sensor EX3 may include the pixels PX of FIG. 1. The image sensor EX3 may be substantially identical to the image sensor EX1 of FIG. 3, except that the top layer 200 and the middle layer 300 are different from those of the image sensor EX1. In FIG. 7, descriptions identical to those given above with reference to FIGS. 3 and 4 may be briefly given or omitted.

Referring to FIG. 7, the image sensor EX3 may include the top layer 200, the middle layer 300, and the bottom layer 400. The image sensor EX3 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The first FD wiring structure 210 may include the first FD wiring layer 207, the first FD plug 208, and the first FD bonding pad 209. A plurality of first FD wiring layers 207 may be provided. From among the plurality of first FD wiring layers 207, two different ones of the first FD wiring layers 207 may be located at different vertical levels. In other words, the plurality of first FD wiring layers 207 may form a multilayer structure.

For example, any one of the plurality of first FD wiring layers 207 may be disposed at the first vertical level LV1, and another one of the plurality of first FD wiring layers 207 may be disposed at the second vertical level LV2. The first vertical level LV1 and the second vertical level LV2 may be located between the first front surface 201f of the first substrate 201 and the bottom surface of the top layer 200. The second vertical level LV2 may be different from the first vertical level LV1. For example, the second vertical level LV2 may be lower than the first vertical level LV1.

Any one of the plurality of first wiring layers 205 may be disposed at the first vertical level LV1, and another one of the plurality of first wiring layers 205 may be disposed at the second vertical level LV2. According to embodiments, in addition to the first vertical level LV1 and the second vertical level LV2, there may be other vertical levels at which the first FD wiring layers 207 and the first wiring layers 205 are arranged. This may vary according to the embodiment of the image sensor EX3 to be manufactured.

The first shield structure 220 may include a first shield wiring layer 221, a first shield plug 222, and a first shield bonding pad 223. A plurality of first shield wiring layers 221 may be provided. Any one of the first shield wiring layers 221 may be disposed at the first vertical level LV1, and another one of the first shield wiring layers 221 may be disposed at the second vertical level LV2.

The horizontal width of the first shield wiring layer 221 disposed at the first vertical level LV1 may be different from the horizontal width of the first shield wiring layer 221 disposed at the second vertical level LV2. The horizontal width of the first shield wiring layer 221 refers to the width of the first shield wiring layer 221 in the first horizontal direction D1 or the width of the first shield wiring layer 221 in the second horizontal direction D2.

Although FIG. 7 shows that the first shield wiring layers 221 at different vertical levels have different horizontal widths from each other, the first shield wiring layers 221 at the same vertical level may have different horizontal widths from each other.

The middle layer 300 may include the second substrate 301, the plurality of second transistors 303, the source follower gate SFG, the source follower source region SFS, the source follower via SFV, the backside bonding through via 330, the second wiring layer 305, the second contact plug 306, the second frontside bonding pad 304, the second via plug 313, the second FD wiring structure 310, the second shield structure 320, and the second insulation layer 311.

The second FD wiring structure 310 may include the second FD wiring layer 307, the second FD plug 308, and the second FD bonding pad 309. A plurality of second FD wiring layers 307 may be provided. From among the plurality of second FD wiring layers 307, two different ones of the second FD wiring layers 307 may be located at different vertical levels. In other words, the plurality of second FD wiring layers 307 may form a multilayer structure.

For example, any one of the plurality of second FD wiring layers 307 may be disposed at a third vertical level LV3, and another one of the plurality of second FD wiring layers 307 may be disposed at a fourth vertical level LV4. The third vertical level LV3 and the fourth vertical level LV4 may be located between the top surface of the middle layer 300 and the second front surface 301f of the second substrate 301. The third vertical level LV3 may be different from the fourth vertical level LV4. For example, the fourth vertical level LV4 may be lower than the third vertical level LV3.

Any one of the plurality of second wiring layers 305 may be disposed at the third vertical level LV3, and another one of the plurality of second wiring layers 305 may be disposed at the fourth vertical level LV4. According to embodiments, in addition to the third vertical level LV3 and the fourth vertical level LV4, there may be other vertical levels at which the second FD wiring layers 307 and the second wiring layers 305 are arranged. This may vary according to the embodiment of the image sensor EX3 to be manufactured.

The second shield structure 320 may include the second shield wiring layer 321, the second shield plug 322, and the second shield bonding pad 323. A plurality of second shield wiring layers 321 may be provided. Any one of the second shield wiring layers 321 may be disposed at the third vertical level LV3, and another one of the second shield wiring layers 321 may be disposed at the fourth vertical level LV4.

The minimum distance between the second FD wiring layer 307 disposed at the third vertical level LV3 and the second shield wiring layer 321 disposed at the third vertical level LV3 may be a first distance L1. The first distance L1 may be a distance in the first horizontal direction D1 or the second horizontal direction D2. The maximum distance between the second FD wiring layer 307 disposed at the third vertical level LV3 and the second shield wiring layer 321 disposed at the third vertical level LV3 may be a second distance L2. The second distance L2 may be a distance in the first horizontal direction D1 or the second horizontal direction D2.

The horizontal distance between the second FD wiring layer 307 disposed at the fourth vertical level LV4 and the second shield wiring layer 321 disposed at the fourth vertical level LV4 may be a third distance L3. The third distance L3 may be a distance in the first horizontal direction D1 or the second horizontal direction D2. The third distance L3 may vary.

The first distance L1 and the second distance L2 may be different from each other. In other words, at the same vertical level, the horizontal distance between the second FD wiring layer 307 and the second shield wiring layer 321 may vary. Also, the third distance L3 may be different from the first distance L1 and the second distance L2. In other words, at different vertical levels, the horizontal distance between the second FD wiring layer 307 and the second shield wiring layer 321 may vary. In other words, the horizontal distance between the FD wiring structure FLS and the shield structure SHS may vary.

The image sensor EX3 according to embodiments of the present disclosure may include the FD wiring structure FLS and the shield structure SHS. The horizontal distance between the FD wiring structure FLS and the shield structure SHS may vary. Even in this case, capacitance may be formed between the shield structure SHS and the FD wiring structure FLS. Therefore, the conversion gain of the image sensor EX3 may be improved and, at the same time, the degree of wiring freedom may be increased.

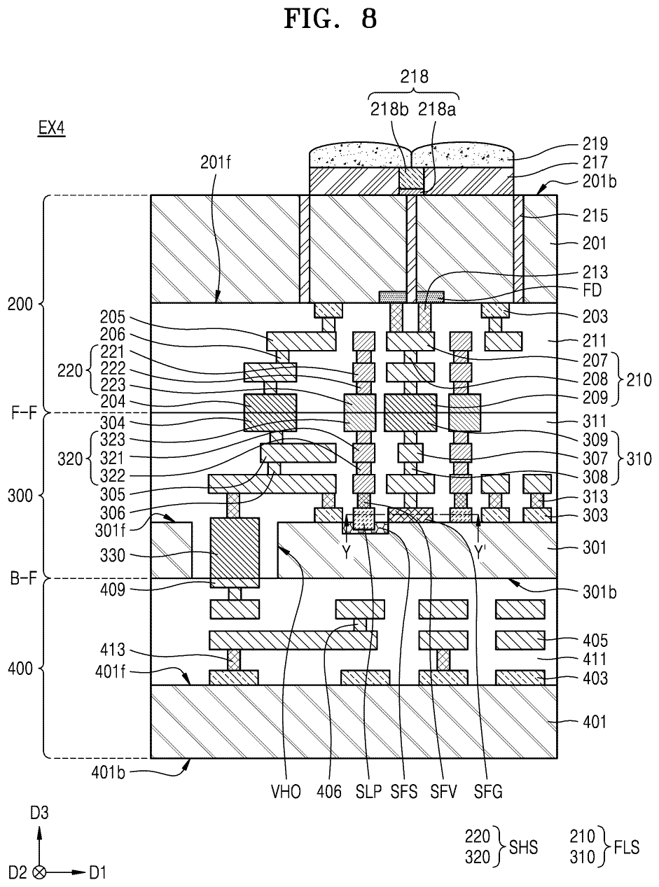

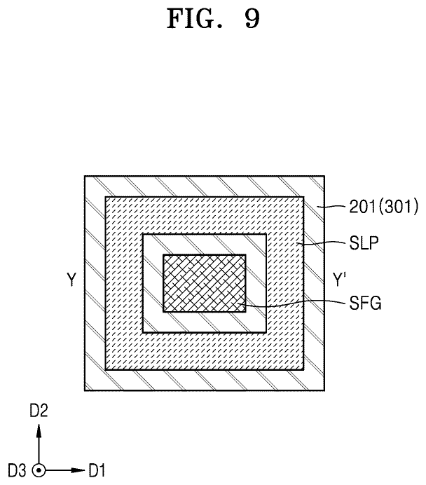

FIG. 8 is a schematic cross-sectional view for describing the structure of an image sensor according to an embodiment. FIG. 9 is a plan view taken along a line Y-Y′ of FIG. 8.

In detail, an image sensor EX4 may be an embodiment of the image sensor 100 of FIG. 1. The image sensor EX4 may include the pixels PX of FIG. 1. The image sensor EX4 may be substantially identical to the image sensor EX1 of FIG. 3, except that the middle layer 300 is different from that of the image sensor EX1. In FIGS. 8 and 9, descriptions identical to those given above with reference to FIGS. 3 and 4 are briefly given or omitted.

Referring to FIGS. 8 and 9, the image sensor EX4 may include the top layer 200, the middle layer 300, and the bottom layer 400. The image sensor EX4 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The middle layer 300 may include the second substrate 301, the plurality of second transistors 303, the source follower gate SFG, the source follower source region SFS, the source follower via SFV, a source follower landing pad SLP, the backside bonding through via 330, the second wiring layer 305, the second contact plug 306, the second frontside bonding pad 304, the second via plug 313, the second FD wiring structure 310, the second shield structure 320, and the second insulation layer 311.

The source follower landing pad SLP may be provided between the source follower source region SFS and the source follower via SFV. The source follower landing pad SLP may connect the source follower source region SFS and the source follower via SFV. At least a portion of the source follower landing pad SLP may be inserted into the source follower source region SFS. The shield structure SHS may be connected to the source follower source region SFS through the source follower via SFV and the source follower landing pad SLP. The shield structure SHS may be connected to the source follower source region SFS.

The vertical level of the top surface of the source follower landing pad SLP may be substantially identical to the vertical level of the top surface of a second transistor 303 and the vertical level of the top surface of the source follower gate SFG. In this specification, the expression “substantially identical” may be a concept that means not only mathematically identical, but also includes an error range in the process. The top surface of the source follower landing pad SLP may be coplanar with the top surface of the second transistor 303 and the top surface of the source follower gate SFG.

In a plan view, the source follower landing pad SLP may surround the source follower gate SFG. In a plan view, the source follower landing pad SLP may have various shapes, such as a polygonal shape, a circular shape, or an oval shape. The source follower landing pad SLP may be spaced apart from the source follower gate SFG in the first horizontal direction D1 and the second horizontal direction D2.

The source follower landing pad SLP may include the same material as the material of the source follower gate SFG. The source follower landing pad SLP and the source follower gate SFG may include the same material. The source follower landing pad SLP may include a conductive material. For example, the source follower landing pad SLP may include polycrystalline silicon doped with an impurity.

The image sensor EX4 according to embodiments of the present disclosure may include the source follower landing pad SLP provided between the source follower source region SFS and the source follower via SFV. The source follower landing pad SLP may connect the shield structure SHS and the source follower source region SFS. In a plan view, the source follower landing pad SLP may surround the source follower gate SFG. Therefore, capacitance may also be formed between the source follower gate SFG and the source follower landing pad SLP and between the source follower gate SFG and the shield structure SHS. Therefore, the capacitance formed between the shield structure SHS and the FD wiring structure FLS may become larger. Therefore, the conversion gain of the image sensor EX4 may further be improved.

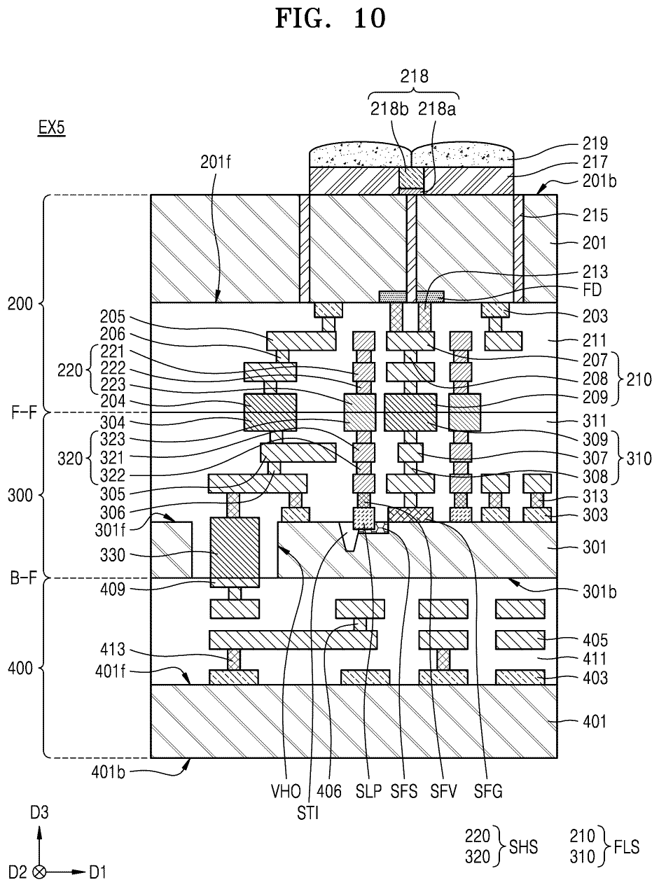

FIG. 10 is a schematic cross-sectional view for describing the structure of an image sensor according to an embodiment.

In detail, an image sensor EX5 may be an embodiment of the image sensor 100 of FIG. 1. The image sensor EX5 may include the pixels PX of FIG. 1. The image sensor EX5 may be substantially identical to the image sensor EX4 of FIGS. 8 and 9, except that the middle layer 300 is different from that of the image sensor EX4. In FIG. 10, descriptions identical to those given above with reference to FIGS. 8 and 9 may be briefly given or omitted.

Referring to FIG. 10, the top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The middle layer 300 may include a device isolation layer STI, the second substrate 301, the plurality of second transistors 303, the source follower gate SFG, the source follower source region SFS, the source follower via SFV, a source follower landing pad SLP, the backside bonding through via 330, the second wiring layer 305, the second contact plug 306, the second frontside bonding pad 304, the second via plug 313, the second FD wiring structure 310, the second shield structure 320, and the second insulation layer 311.

The device isolation layer STI may be disposed in the second substrate 301. The device isolation layer STI may provide electrical insulation between the plurality of second transistors 303. According to an embodiment, the device isolation layer STI may be disposed in contact with the source follower source region SFS. The device isolation layer STI may be inserted downward in the vertical direction D3 from the second front surface 301f of the second substrate 301.

The source follower landing pad SLP may be provided between the source follower source region SFS and the source follower via SFV. The source follower landing pad SLP may connect the source follower source region SFS and the source follower via SFV. At least a portion of the source follower landing pad SLP may be inserted into the source follower source region SFS. At least another portion of the source follower landing pad SLP may be inserted into the device isolation layer STI. The source follower landing pad SLP may be disposed on the source follower source region SFS and on the device isolation layer STI. The source follower landing pad SLP may simultaneously contact the source follower source region SFS and the device isolation layer STI.

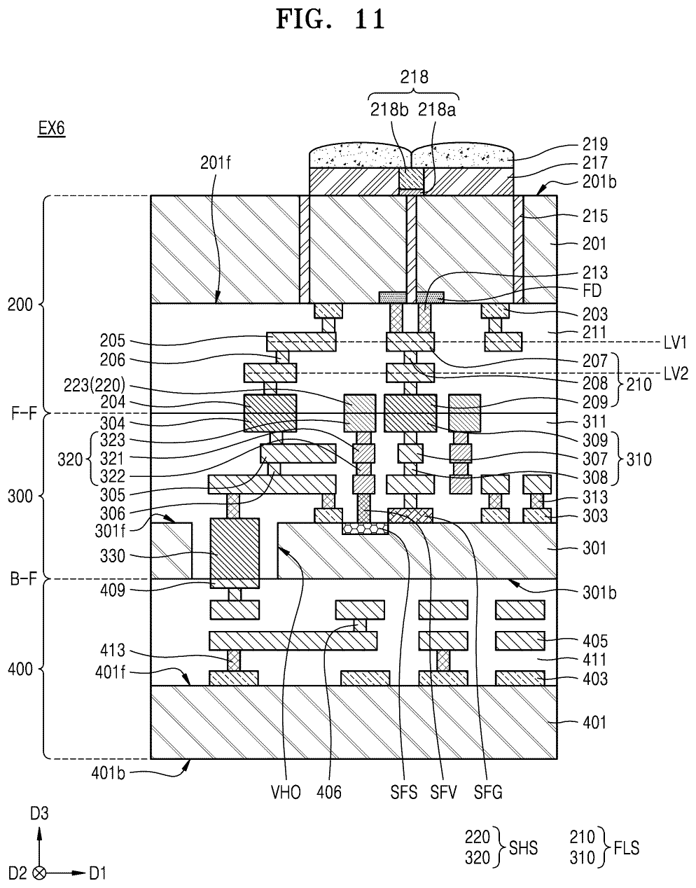

FIG. 11 is a schematic cross-sectional view for describing the structure of an image sensor according to an embodiment.

In detail, an image sensor EX6 may be an embodiment of the image sensor 100 of FIG. 1. The image sensor EX6 may include the pixels PX of FIG. 1. The image sensor EX6 may be substantially identical to the image sensor EX1 of FIG. 3, except that the top layer 200 is different from that of the image sensor EX1. In FIG. 11, descriptions identical to those given above with reference to FIGS. 3 and 4 may be briefly given or omitted.

Referring to FIG. 11, the image sensor EX6 may include the top layer 200, the middle layer 300, and the bottom layer 400. The image sensor EX6 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The first FD wiring structure 210 may include the first FD wiring layer 207, the first FD plug 208, and the first FD bonding pad 209. A plurality of first FD wiring layers 207 may be provided. From among the plurality of first FD wiring layers 207, two different ones of the first FD wiring layers 207 may be located at different vertical levels. In other words, the plurality of first FD wiring layers 207 may form a multilayer structure.

For example, any one of the plurality of first FD wiring layers 207 may be disposed at the first vertical level LV1, and another one of the plurality of first FD wiring layers 207 may be disposed at the second vertical level LV2. The first vertical level LV1 and the second vertical level LV2 may be located between the first front surface 201f of the first substrate 201 and the bottom surface of the top layer 200. The second vertical level LV2 may be different from the first vertical level LV1. For example, the second vertical level LV2 may be lower than the first vertical level LV1.

Any one of the plurality of first wiring layers 205 may be disposed at the first vertical level LV1, and another one of the plurality of first wiring layers 205 may be disposed at the second vertical level LV2. According to embodiments, in addition to the first vertical level LV1 and the second vertical level LV2, there may be other vertical levels at which the first FD wiring layers 207 and the first wiring layers 205 are arranged. This may vary according to the embodiment of the image sensor EX6 to be manufactured.

Unlike the image sensor EX1 of FIG. 3, the first shield structure 220 of the image sensor EX6 of FIG. 11 may not include the first shield wiring layer 221 (see FIG. 3) and the first shield plug 222 (see FIG. 3). Therefore, the first shield wiring layer 221 (see FIG. 3) may be omitted at the first vertical level LV1 and the second vertical level LV2. The first shield structure 220 may include only the first shield bonding pad 223.

Even when the first shield structure 220 includes only the first shield bonding pad 223, capacitance may be formed between the shield structure SHS and the FD wiring structure FLS. Therefore, the conversion gain of the image sensor EX6 may be improved and, at the same time, the wiring freedom of the image sensor EX6 may be increased.

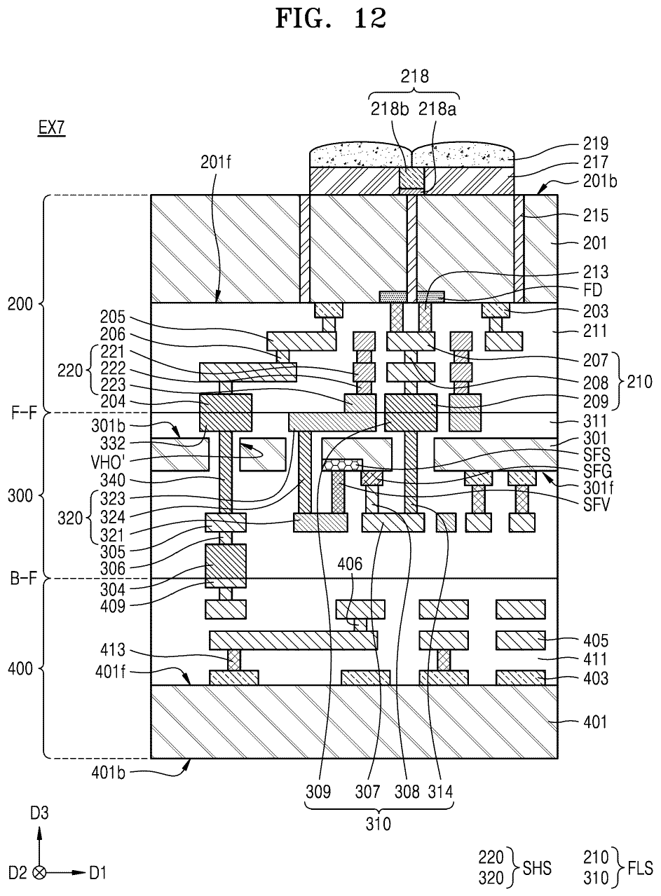

FIG. 12 is a schematic cross-sectional view for describing the structure of an image sensor according to an embodiment.

In detail, an image sensor EX7 may be an embodiment of the image sensor 100 of FIG. 1. The image sensor EX7 may include the pixels PX of FIG. 1. The image sensor EX7 may be substantially identical to the image sensor EX1 of FIG. 3, except that the top layer 200 and the middle layer 300 are different from those of the image sensor EX1. In FIG. 12, descriptions identical to those given above with reference to FIGS. 3 and 4 may be briefly given or omitted.

Referring to FIG. 12, the image sensor EX7 may include the top layer 200, the middle layer 300, and the bottom layer 400. The image sensor EX7 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The middle layer 300 may include the second substrate 301, the plurality of second transistors 303, the source follower gate SFG, the source follower source region SFS, the source follower via SFV, a backside bonding pad 332, the second wiring layer 305, the second contact plug 306, the second frontside bonding pad 304, the second via plug 313, the second FD wiring structure 310, the second shield structure 320, a second connection via plug 340, and the second insulation layer 311.

The first frontside bonding pad 204 included in the top layer 200 may be bonded to the backside bonding pad 332 included in the middle layer 300. The first insulation layer 211 included in the top layer 200 may be bonded to the second insulation layer 311 included in the middle layer 300. The top layer 200 and the middle layer 300 may have a boundary surface F-B at which the front surface of the top layer 200 and the back surface of the middle layer 300 are bonded to each other.

The second substrate 301 may include a second front surface 301f and a second back surface 301b opposite of the second front surface 301f. The second transistor 303 and the source follower gate SFG may be arranged on the second front surface 301f. In FIG. 12, second source and drain regions constituting the second transistors 303 are arranged in the second substrate 301, but illustration thereof is omitted for convenience.

The second wiring layer 305 and the second contact plug 306 may be connected to the second transistor 303 through the second via plug 313. The second wiring layer 305 and the second contact plug 306 may be connected to the second frontside bonding pad 304. The second wiring layer 305 and the second contact plug 306 may be connected to the backside bonding pad 332 through the second connection via plug 340. The second connection via plug 340 may be disposed in a through via hole VHO′ penetrating through the second substrate 301.

The backside bonding pad 332 may be disposed adjacent to the second back surface 301b of the second substrate 301. The backside bonding pad 332 may be disposed within the upper portion of middle layer 300. The backside bonding pad 332 may be connected to the first frontside bonding pad 204.

The second FD wiring structure 310 may further include a first connection via plug 314 penetrating through the second substrate 301. The first connection via plug 314 may be spaced apart from the second substrate 301 with the second insulation layer 311 therebetween. The second FD bonding pad 309 may be connected to the second FD wiring layer 307 and the second FD plug 308 through the first connection via plug 314. The first connection via plug 314 may be connected to the source follower gate SFG through the second FD wiring layer 307 and the second FD plug 308.

The second shield structure 320 may further include a shield via plug 324 penetrating through the second substrate 301. Unlike the second shield structure 320 of FIG. 3, the second shield structure 320 of FIG. 12 may not include the second shield plug 322 (see FIG. 3). The shield via plug 324 may be spaced apart from the second substrate 301 with the second insulation layer 311 therebetween. The second shield bonding pad 323 may be connected to the second shield wiring layer 321 and the source follower via SFV through the shield via plug 324. The shield via plug 324 may be connected to the source follower source region SFS through the second shield wiring layer 321 and the source follower via SFV. According to embodiments, the first shield structure 220 and the second shield structure 320 may be connected to each other.

The length of first connection via plug 314 in the vertical direction may be greater than the length of the second FD plug 308 in the vertical direction. The length of the second connection via plug 340 in the vertical direction may be greater than the length of the second contact plug 306 in the vertical direction. The length of the shield via plug 324 in the vertical direction may be greater than the length of the source follower via SFV in the vertical direction. The first connection via plug 314, the second connection via plug 340, and the shield via plug 324 may include a metal (e.g., Cu or W).

The second insulation layer 311 may be disposed on the second back surface 301b and the second front surface 301f of the second substrate 301. The second insulation layer 311 may have a single-layer structure or a multilayer structure. The second insulation layer 311 may not cover the top surface of the second FD bonding pad 309, the top surface of the second shield bonding pad 323, the top surface of the backside bonding pad 332, and the bottom surface of the second frontside bonding pad 304.

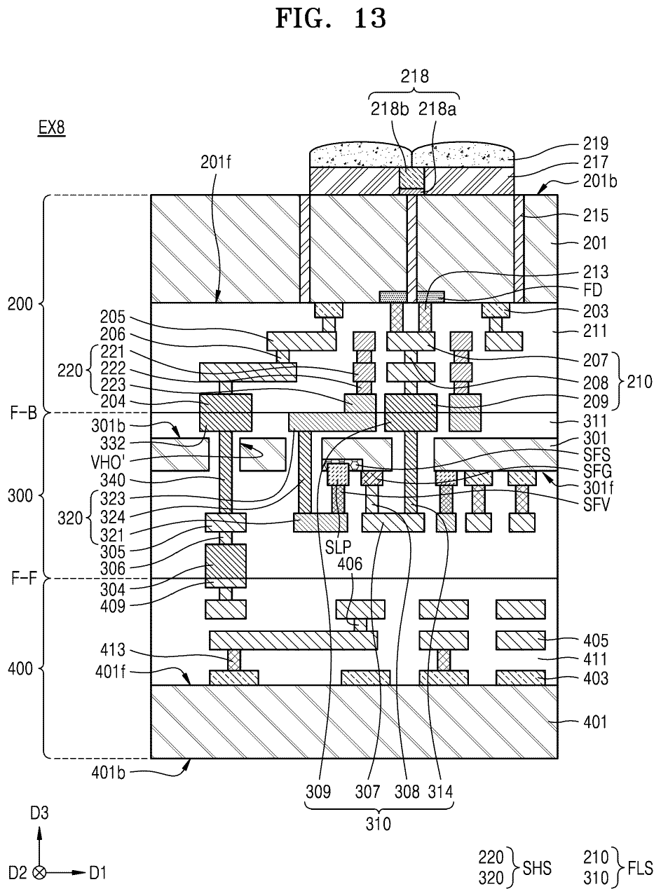

FIG. 13 is a schematic cross-sectional view for describing the structure of an image sensor according to an embodiment.

In detail, an image sensor EX8 may be an embodiment of the image sensor 100 of FIG. 1. The image sensor EX8 may include the pixels PX of FIG. 1. The image sensor EX8 may be substantially identical to the image sensor EX7 of FIG. 12, except that the middle layer 300 is different from that of the image sensor EX7. In FIG. 13, descriptions identical to those given above with reference to FIG. 12 may be briefly given or omitted.

Referring to FIG. 13, the source follower landing pad SLP may be provided between the source follower source region SFS and the source follower via SFV. The source follower source region SFS and the source follower via SFV may be connected to each other through the source follower landing pad SLP. The bottom surface of the source follower landing pad SLP may be coplanar with the bottom surface of the source follower gate SFG and the bottom surface of the second transistor 303.

At least a portion of the source follower landing pad SLP may be inserted into the source follower source region SFS. The shield structure SHS may be connected to the source follower source region SFS through the source follower via SFV and the source follower landing pad SLP. The shield structure SHS may be connected to the source follower source region SFS.

In a plan view, the source follower landing pad SLP may surround the source follower gate SFG, similarly as in FIG. 9. In a plan view, the source follower landing pad SLP may have various shapes, such as a polygonal shape, a circular shape, or an oval shape. The source follower landing pad SLP may be spaced apart from the source follower gate SFG in the first horizontal direction D1 and the second horizontal direction D2.

The source follower landing pad SLP may include a conductive material. For example, the source follower landing pad SLP may include polycrystalline silicon doped with an impurity.

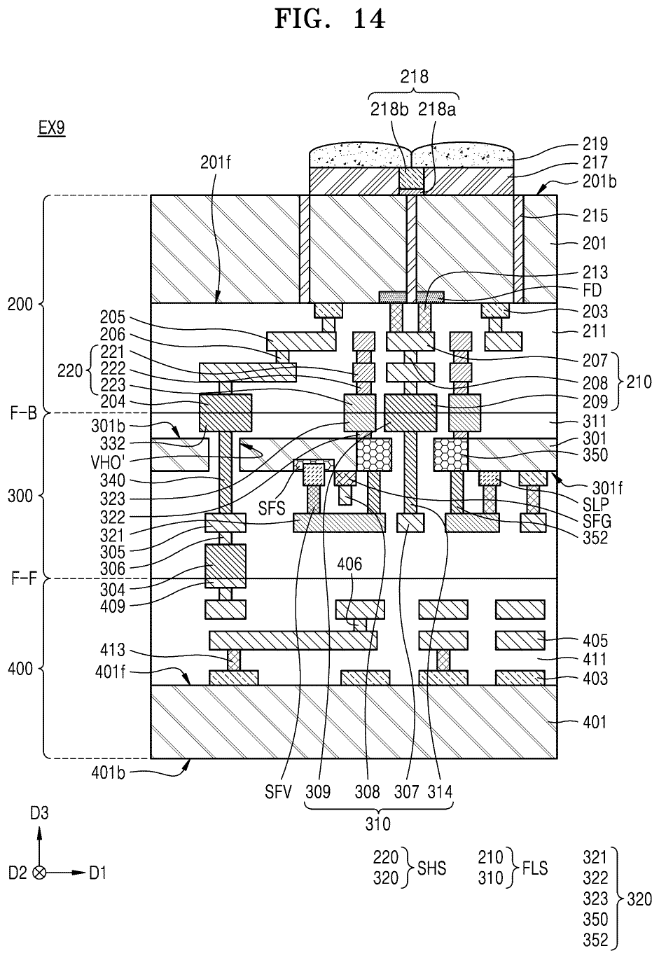

FIG. 14 is a schematic cross-sectional view for describing the structure of an image sensor according to an embodiment.

In detail, an image sensor EX9 may be an embodiment of the image sensor 100 of FIG. 1. The image sensor EX9 may include the pixels PX of FIG. 1. The image sensor EX9 may be substantially identical to the image sensor EX1 of FIG. 3, except that the middle layer 300 is different from that of the image sensor EX1. In FIG. 14, descriptions identical to those given above with reference to FIG. 3 may be briefly given or omitted.

Referring to FIG. 14, the image sensor EX9 may include the top layer 200, the middle layer 300, and the bottom layer 400. The image sensor EX9 may include three layers in which the bottom layer 400, the middle layer 300, and the top layer 200 are bonded to one another.

The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220.

The middle layer 300 may include the second substrate 301, the plurality of second transistors 303, the source follower gate SFG, the source follower source region SFS, the source follower via SFV, the source follower landing pad SLP, the backside bonding pad 332, the second wiring layer 305, the second contact plug 306, the second frontside bonding pad 304, the second via plug 313, the second FD wiring structure 310, the second shield structure 320, the second connection via plug 340, and the second insulation layer 311.

The first frontside bonding pad 204 included in the top layer 200 may be bonded to the backside bonding pad 332 included in the middle layer 300. The first insulation layer 211 included in the top layer 200 may be bonded to the second insulation layer 311 included in the middle layer 300. The top layer 200 and the middle layer 300 may have a boundary surface F-B at which the front surface of the top layer 200 and the back surface of the middle layer 300 are bonded to each other.

The second substrate 301 may include a second front surface 301f and a second back surface 301b opposite to the second front surface 301f. The second transistor 303 and the source follower gate SFG may be arranged on the second front surface 301f. In FIG. 14, second source and drain regions constituting the second transistors 303 are arranged in the second substrate 301, but illustration thereof is omitted for convenience.

The second wiring layer 305 and the second contact plug 306 may be connected to the second transistor 303 through the second via plug 313. The second wiring layer 305 and the second contact plug 306 may be connected to the second frontside bonding pad 304. The second wiring layer 305 and the second contact plug 306 may be connected to the backside bonding pad 332 through the second connection via plug 340. The second connection via plug 340 may be disposed in a through via hole VHO′ penetrating through the second substrate 301.

The backside bonding pad 332 may be disposed adjacent to the second back surface 301b of the second substrate 301. The backside bonding pad 332 may be disposed within the upper portion of middle layer 300. The backside bonding pad 332 may be connected to the first frontside bonding pad 204.

The second FD wiring structure 310 may further include a first connection via plug 314 penetrating through the second substrate 301. The first connection via plug 314 may be spaced apart from the second substrate 301 with the second insulation layer 311 therebetween.

The second FD bonding pad 309 may be connected to the second FD wiring layer 307 and the second FD plug 308 through the first connection via plug 314. According to embodiments, the second FD wiring layer 307 connected to the first connection via plug 314 may be connected to the second FD plug 308 connected to the source follower gate SFG. The first connection via plug 314 may be connected to the source follower gate SFG through the second FD wiring layer 307 and the second FD plug 308.

The length of first connection via plug 314 in the vertical direction may be greater than the length of the second FD plug 308 in the vertical direction. The length of the second connection via plug 340 in the vertical direction may be greater than the length of the second contact plug 306 in the vertical direction. The first connection via plug 314 and the second connection via plug 340 may include a metal (e.g., Cu or W).

The second insulation layer 311 may be disposed on the second back surface 301b and the second front surface 301f of the second substrate 301. The second insulation layer 311 may have a single-layer structure or a multilayer structure. The second insulation layer 311 may not cover the top surface of the second FD bonding pad 309, the top surface of the second shield bonding pad 323, the top surface of the backside bonding pad 332, and the bottom surface of the second frontside bonding pad 304.

The second shield structure 320 may further include an impurity region 350 disposed in the second substrate 301, and a shield connection plug 352 connecting the impurity region 350 and the second shield wiring layer 321. The impurity region 350 may be a region doped with an impurity in the second substrate 301. The impurity may have P-type conductivity or N-type conductivity.

The impurity region 350 may be connected to the second shield bonding pad 323 through the second shield plug 322. The impurity region 350 may be connected to the second shield wiring layer 321 through the shield connection plug 352. In a plan view, the impurity region 350 may have an annular shape.

The second shield wiring layer 321 may be connected to the source follower source region SFS through the source follower via SFV and the source follower landing pad SLP. The shield connection plug 352 may include a metal (e.g., Cu or W).

The source follower landing pad SLP may be provided between the source follower source region SFS and the source follower via SFV. The source follower source region SFS and the source follower via SFV may be connected to each other through the source follower landing pad SLP. The bottom surface of the source follower landing pad SLP may be coplanar with the bottom surface of the source follower gate SFG and the bottom surface of the second transistor 303.

At least a portion of the source follower landing pad SLP may be inserted into the source follower source region SFS. The shield structure SHS may be connected to the source follower source region SFS through the source follower via SFV and the source follower landing pad SLP. The shield structure SHS may be connected to the source follower source region SFS.

In a plan view, the source follower landing pad SLP may surround the source follower gate SFG, similarly as in FIG. 9. In a plan view, the source follower landing pad SLP may have various shapes, such as a polygonal shape, a circular shape, or an oval shape. The source follower landing pad SLP may be spaced apart from the source follower gate SFG in the first horizontal direction D1 and the second horizontal direction D2.

The source follower landing pad SLP may include a conductive material. For example, the source follower landing pad SLP may include polycrystalline silicon doped with an impurity.

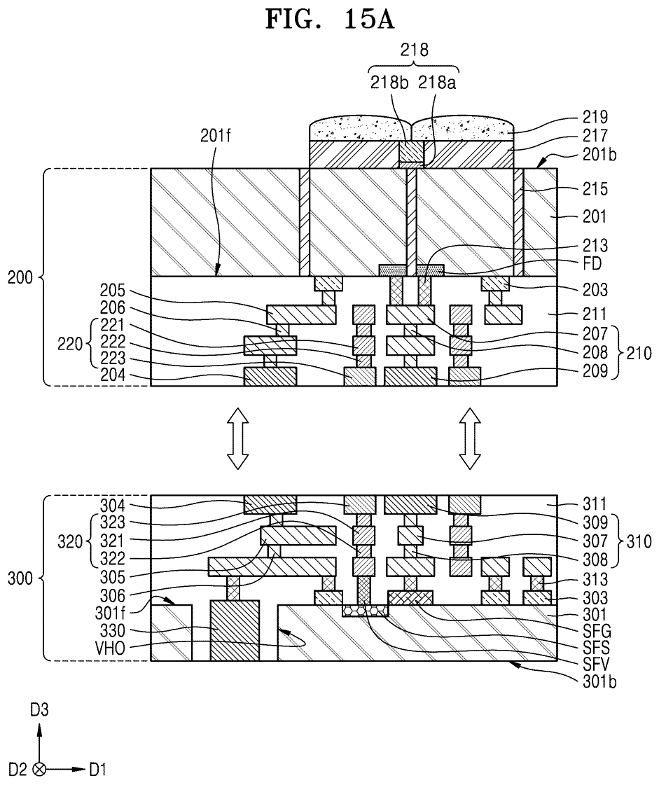

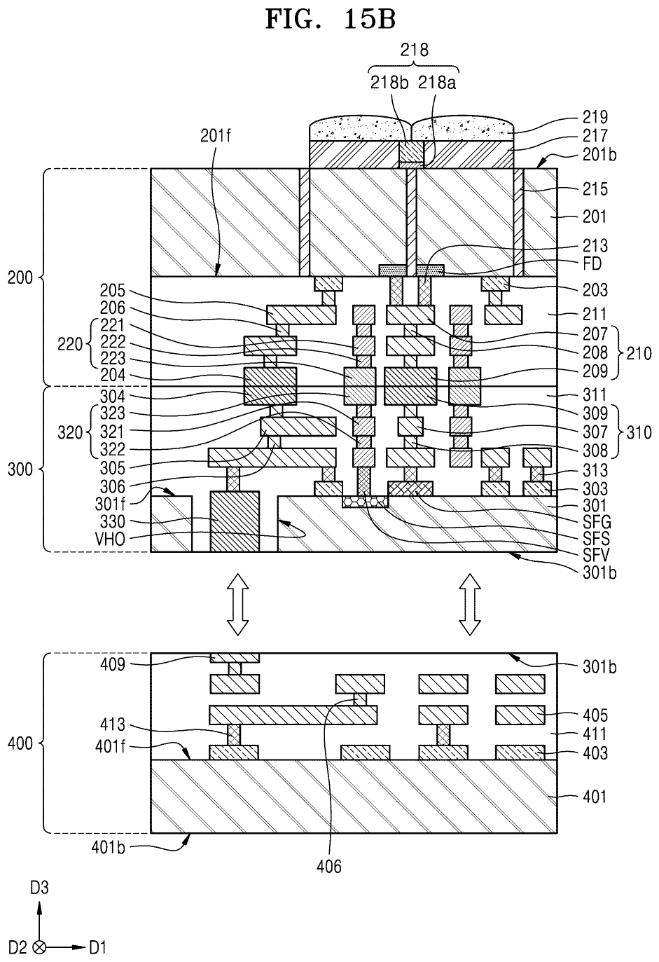

FIGS. 15A and 15B are cross-sectional views for describing a method of manufacturing the image sensor of FIG. 3, according to an embodiment.

In detail, descriptions identical to those given above with reference to FIG. 3 may be briefly given or omitted. Referring to FIG. 15A, the top layer 200 may be prepared. The top layer 200 may include the first substrate 201, the plurality of first transistors 203, the first wiring layer 205, the first contact plug 206, the first frontside bonding pad 204, the first via plug 213, the first insulation layer 211, the pixel isolation layer 215, the color filter 217, the lens 219, the first FD wiring structure 210, and the first shield structure 220. The first substrate 201 may include a first front surface 201f and a first back surface 201b opposite to the first front surface 201f.

The middle layer 300 may be prepared. The middle layer 300 may include the second substrate 301, the plurality of second transistors 303, the source follower gate SFG, the source follower source region SFS, the source follower via SFV, the backside bonding through via 330, the second wiring layer 305, the second contact plug 306, the second frontside bonding pad 304, the second via plug 313, the second FD wiring structure 310, the second shield structure 320, and the second insulation layer 311.

The second substrate 301 may include a second front surface 301f and a second back surface 301b opposite to the second front surface 301f. The through via hole VHO penetrating through the second front surface 301f and the second back surface 301b may be formed in the second substrate 301. The backside bonding through via 330 insulated by the second insulation layer 311 may be formed in the through via hole VHO.

The first frontside bonding pad 204 constituting the top layer 200 is bonded to the second frontside bonding pad 304 constituting the middle layer 300 in the direction indicated by the arrow. The first insulation layer 211 constituting the top layer 200 is bonded to the second insulation layer 311 constituting the middle layer 300 in the direction indicated by the arrow. When the first frontside bonding pad 204 and the second frontside bonding pad 304 are formed of Cu layers, Cu pads may be bonded to each other. At this time, the first FD bonding pad 209 and the second FD bonding pad 309 may be bonded to each other, and the first shield bonding pad 223 and the second shield bonding pad 323 may be bonded to each other.

Referring to FIG. 15B, the top layer 200 and the middle layer 300 that are bonded to each other as described above with reference to FIG. 15A are prepared. Next, the bottom layer 400 is prepared. The bottom layer 400 may include the third substrate 401, the plurality of third transistors 403, the third wiring layer 405, the third contact plug 406, the third frontside bonding pad 409, the third via plug 413, and the third insulation layer 411.

The second insulation layer 311 and the second substrate 301 constituting the middle layer 300 are bonded to the third insulation layer 411 constituting the bottom layer 400 in the direction indicated by the arrow. The backside bonding through via 330 and the third frontside bonding pad 409 may be bonded to each other. When the backside bonding through via 330 and the third frontside bonding pad 409 are formed of Cu layers, a Cu via and a Cu pad may be bonded to each other. Through the above-stated process, the image sensor EX1 of FIG. 3 may be manufactured.

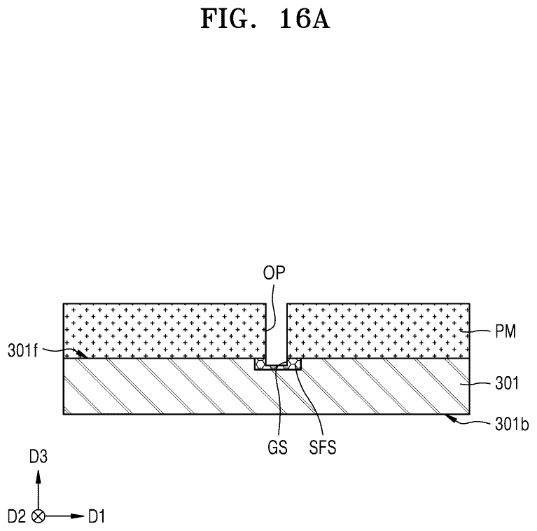

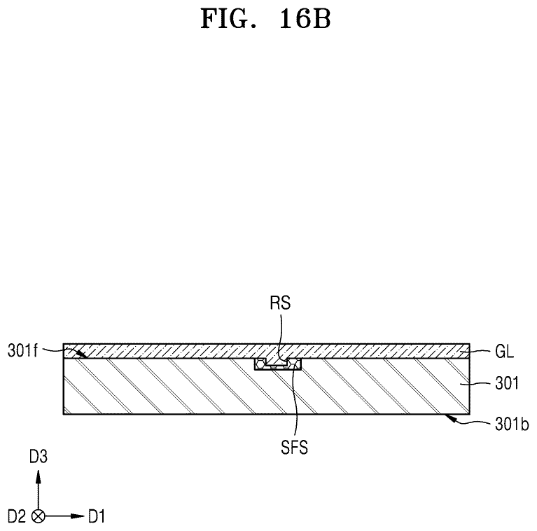

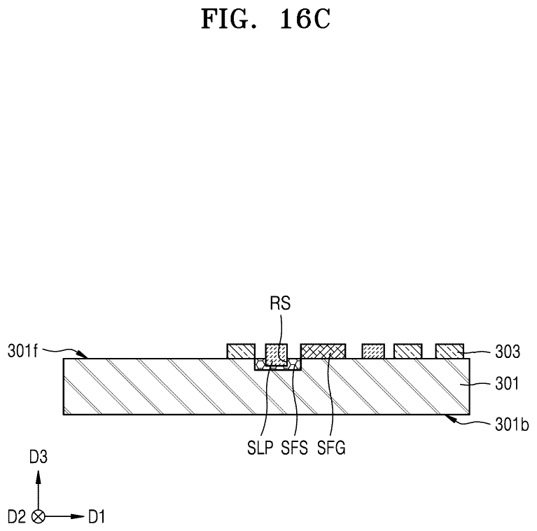

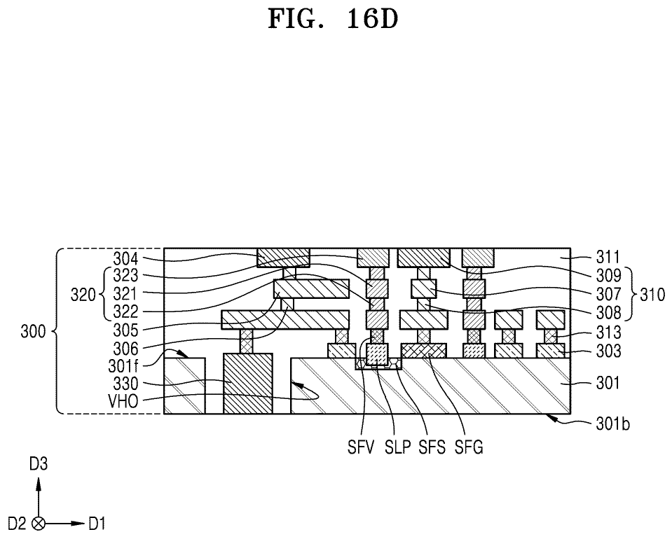

FIGS. 16A to 16D are cross-sectional views for describing a method of manufacturing the image sensor of FIG. 8, according to an embodiment. In detail, FIGS. 16A and 16D are cross-sectional views for describing a method of fabricating the middle layer 300 of the image sensor EX4 of FIG. 8.

Referring to FIG. 16A, the second substrate 301 may be prepared. The second substrate 301 may include a second front surface 301f and a second back surface 301b opposite to the second front surface 301f. The source follower source region SFS may be formed by performing an impurity implantation process into the second substrate 301.

After forming a photo mask layer on the second front surface 301f of the second substrate 301, an exposure and development process may be performed on the photo mask layer. Due to the exposure and development process, a photo mask pattern PM may be formed from the photo mask layer. The photo mask pattern PM may include an opening OP exposing a portion of the source follower source region SFS.

An etching process may be performed on the second substrate 301 by using the photo mask pattern PM as an etch mask. Due to the etching process, a portion of the source follower source region SFS exposed through the opening OP is etched, and thus a recess RS (see FIG. 16B) may be formed downward in the vertical direction D3 from the second front surface 301f of the second substrate 301.

Referring to FIG. 16B, the photo mask pattern PM may be removed. Subsequently, a preliminary conductive layer GL covering the second front surface 301f of the second substrate 301 may be formed. The preliminary conductive layer GL may include, for example, polycrystalline silicon or a metal. The preliminary conductive layer GL may fill the recess RS.

Referring to FIG. 16C, the second transistor 303, the source follower gate SFG, and the source follower landing pad SLP may be formed by patterning the preliminary conductive layer GL of FIG. 16B. In detail, the second transistor 303 formed by patterning the preliminary conductive layer GL may be a transistor gate of the second transistor 303. The second transistor 303, the source follower gate SFG, and the source follower landing pad SLP may be formed simultaneously from the preliminary conductive layer GL.

Referring to FIG. 16D, subsequently, the second via plug 313, the second wiring layer 305, the second contact plug 306, the second FD wiring structure 310, the second shield structure 320, the second frontside bonding pad 304, and the backside bonding through via 330 may be formed. Therefore, the middle layer 300 of the image sensor EX4 of FIG. 8 may be fabricated.

Next, similar to as described with reference to FIGS. 15A and 15B, the top layer 200 and the bottom layer 400 may be prepared, the top layer 200 and the middle layer 300 may be bonded to each other, and the middle layer 300 and the bottom layer 400 may be bonded to each other. Therefore, the image sensor EX4 of FIG. 8 may be manufactured.

While non-limiting example embodiments have been particularly shown and described with reference to the drawings, it will be understood that various changes in form and details may be made therein without departing from the spirit and scope of the present disclosure.

What is claimed is:

1. An image sensor comprising:
a top layer comprising:
a first substrate;
a floating diffusion (FD) node within the first substrate;
a first FD wiring structure connected to the FD node; and
a first shield structure next to the first FD wiring structure;
a middle layer bonded to and below the top layer, wherein the middle layer comprises:
a second substrate;
a source follower gate on the second substrate;
a source follower source region in the second substrate;
a second FD wiring structure connected to the first FD wiring structure and the source follower gate;
a second shield structure connected to the first shield structure and the source follower source region; and
a source follower landing pad between the second shield structure and the source follower source region and spaced apart from the source follower gate; and
a bottom layer bonded to and below the middle layer, wherein the bottom layer comprises a third substrate and transistors on the third substrate.

2. The image sensor of claim 1, wherein the first shield structure is spaced apart from the first FD wiring structure in a horizontal direction and surrounds the first FD wiring structure, and
wherein the second shield structure is spaced apart from the second FD wiring structure in the horizontal direction and surrounds the second FD wiring structure.

3. The image sensor of claim 1, wherein the first FD wiring structure comprises a first FD wiring layer at a first vertical level and a second FD wiring layer at a second vertical level different from the first vertical level, and
wherein the first shield structure comprises a first shield wiring layer at only one from among the first vertical level and the second vertical level.

4. The image sensor of claim 1, wherein a top surface of the source follower gate and a top surface of the source follower landing pad are coplanar with each other.

5. The image sensor of claim 1, wherein the first shield structure comprises a first shield wiring layer at a first vertical level and a second shield wiring layer at a second vertical level different from the first vertical level, and
wherein a horizontal distance from the first FD wiring structure to the first shield wiring layer is different from a horizontal distance from the first FD wiring structure to the second shield wiring layer.

6. The image sensor of claim 1, wherein the first shield structure comprises a first shield wiring layer at a first vertical level and a second shield wiring layer at a second vertical level different from the first vertical level, and
wherein a horizontal width of the first shield wiring layer is different from a horizontal width of the second shield wiring layer.

7. The image sensor of claim 1, wherein the middle layer further comprises a device isolation layer in the second substrate and in contact with the source follower source region, and
wherein at least a portion of the source follower landing pad is in contact with the device isolation layer.

8. The image sensor of claim 1, wherein the second FD wiring structure comprises a second FD bonding pad bonded to a first FD bonding pad included in the first FD wiring structure, and a first connection via plug connected to the second FD bonding pad and penetrating through the second substrate.

9. The image sensor of claim 8, wherein the second shield structure comprises a second shield bonding pad bonded to a first shield bonding pad included in the first shield structure, and a shield via plug connected to the second shield bonding pad and penetrating through the second substrate.

10. The image sensor of claim 1, wherein the first shield structure comprises a plurality of first shield wiring layers arranged at different vertical levels from each other, and a first shield plug connecting the plurality of first shield wiring layers respectively arranged at the different vertical levels to each other in a vertical direction, and
wherein the plurality of first shield wiring layers extend in a horizontal direction.

11. The image sensor of claim 1, wherein the source follower landing pad surrounds the source follower gate.

12. An image sensor comprising:
a top layer comprising:
a first substrate;
a floating diffusion (FD) node within the first substrate;
a first FD wiring structure connected to the FD node; and
a first shield structure next to the first FD wiring structure;
a middle layer bonded to and below the top layer, wherein the middle layer comprises:
a second substrate comprising a second front surface and a second back surface opposite to the second front surface;
a source follower gate on the second front surface of the second substrate;
a source follower source region in the second substrate;
a second FD wiring structure connected to the first FD wiring structure and the source follower gate; and
a second shield structure connected to the first shield structure and the source follower source region; and
a bottom layer bonded to and below the middle layer, wherein the bottom layer comprises a third substrate and transistors on the third substrate,
wherein the second shield structure comprises:
a second shield bonding pad bonded to a first shield bonding pad included in the first shield structure; and
an impurity region in the second substrate and connected to the second shield bonding pad.

13. The image sensor of claim 12, wherein the second shield structure further comprises:
a second shield wiring layer spaced apart from the second substrate;
a second shield plug connecting the impurity region and the second shield bonding pad; and
a shield connection plug connecting the impurity region and the second shield wiring layer.

14. The image sensor of claim 13, wherein the middle layer further comprises a source follower landing pad between the source follower source region and the second shield plug, and
wherein at least a portion of the source follower landing pad is surrounded by the source follower source region.

15. The image sensor of claim 14, wherein the second FD wiring structure comprises a second FD bonding pad bonded to a first FD bonding pad included in the first FD wiring structure, and a first connection via plug connected to the second FD bonding pad and penetrating through the second substrate.

16. The image sensor of claim 12, wherein the first shield structure surrounds the first FD wiring structure, and
wherein the second shield structure surrounds the second FD wiring structure.

17. The image sensor of claim 12, wherein the top layer comprises a first frontside bonding pad,
wherein the middle layer comprises a second frontside bonding pad and a second backside bonding pad,
wherein the bottom layer comprises a third frontside bonding pad,
wherein the first frontside bonding pad is bonded to the second backside bonding pad, and
wherein the second frontside bonding pad is bonded to the third frontside bonding pad.

18. An image sensor comprising:
a top layer comprising:
a first substrate;
a pixel isolation layer in the first substrate and defining a pixel;
a photo diode arranged in the first substrate and constituting the pixel;
a transmission transistor for transmitting an electrical signal generated by the photo diode;
a floating diffusion (FD) node in the first substrate and connected to the transmission transistor;
a first FD wiring structure connected to the FD node;
a first shield structure next to the first FD wiring structure; and
a first wiring layer spaced apart from the first FD wiring structure and the first shield structure;
a middle layer bonded to and below the top layer, wherein the middle layer comprises:
a second substrate;
a source follower gate on the second substrate;
a source follower source region in the second substrate;
a second FD wiring structure connected to the first FD wiring structure and the source follower gate;
a second shield structure connected to the first shield structure and the source follower source region;
a source follower landing pad between the second shield structure and the source follower source region and surrounding the source follower gate; and
a second wiring layer spaced apart from the second FD wiring structure and the second shield structure; and
a bottom layer bonded to and below the middle layer, wherein the bottom layer comprises:
a third substrate;
transistors arranged on the third substrate;
a third wiring layer connected to a transistor; and
a third via plug between the transistor and the third wiring layer.

19. The image sensor of claim 18, wherein a top surface of the source follower landing pad is coplanar with a top surface of the source follower gate.

20. The image sensor of claim 18, wherein the first FD wiring structure comprises a first FD wiring layer at a first vertical level and a second FD wiring layer at a second vertical level different from the first vertical level, and
wherein the first shield structure comprises a first shield wiring layer at only one from among the first vertical level and the second vertical level.
